(19) United States
(12) Patent Application Publication
(10) Pub. No.: US 2024/0421130 A1
(43) Pub. Date: Dec. 19, 2024

(54) SEMICONDUCTOR PACKAGE AND METHOD OF MANUFACTURING THE SEMICONDUCTOR PACKAGE

(71) Applicant: Samsung Electronics Co., Ltd., Suwon-si (KR)

(72) Inventor: Sanghoon Lee, Suwon-si (KR)

(21) Appl. No.: 18/585,945

(22) Filed: Feb. 23, 2024

(30) Foreign Application Priority Data
Jun. 19, 2023 (KR) 10-2023-0077838

(51) Int. Cl. H01L 25/065; H01L 21/768; H01L 23/00; H01L 23/48; H01L 23/532

(52) U.S. Cl. CPC H01L 25/0657; H01L 21/76898; H01L 23/481; H01L 23/53295; H01L 24/05; H01L 24/16; H01L 24/81; H01L 2224/05647; H01L 2224/16225; H01L 2224/80895; H01L 2224/81801; H01L 2225/06541; H01L 2924/1431

(57) ABSTRACT

A semiconductor package includes a buffer die, an intermediate core die stack stacked on the buffer die, the intermediate core die stack including a plurality of intermediate core dies and a first gap filling portion covering outer surfaces of the plurality of intermediate core dies, and a top core die stack stacked on the intermediate core die stack, the top core die stack including a top core die and a second gap filling portion covering an outer surface of the top core die. The first gap filling portion and the second gap filling portion are directly bonded to each other.

### PRIORITY STATEMENT

This application claims priority under 35 U.S.C. § 119 to Korean Patent Application No. 10-2023-0077838, filed on Jun. 19, 2023 in the Korean Intellectual Property Office (KIPO), the contents of which are herein incorporated by reference in their entirety.

### BACKGROUND

### 1. Field

Example embodiments relate to a semiconductor package and a method of manufacturing the semiconductor package. More particularly, example embodiments relate to a semiconductor package including a plurality of sequentially stacked semiconductor chips and a method of manufacturing the same.

### 2. Description of the Related Art

To manufacture a multi-chip package in which at least four semiconductor chips are stacked, in a die to wafer bonding process, pad-to-pad direct bonding may be performed without using solder bumps. In this case, since a top core die has a relatively large thickness, it may be difficult to deform the top core die during bonding in the die to wafer bonding process, so voids generated at a bonding interface may not be discharged, resulting in deterioration of the bonding quality between surfaces at the interface in hybrid bonding.

### SUMMARY

Example embodiments provide a semiconductor package having improved bonding quality.

Example embodiments provide a method of manufacturing the semiconductor package.

According to example embodiments, a semiconductor package includes a buffer die, an intermediate core die stack stacked on the buffer die, the intermediate core die stack including a plurality of intermediate core dies and a first gap filling portion covering outer surfaces of the plurality of intermediate core dies, and a top core die stack stacked on the intermediate core die stack, the top core die stack including a top core die and a second gap filling portion covering an outer surface of the top core die. The first gap filling portion and the second gap filling portion are directly bonded to each other.

According to example embodiments, a semiconductor package includes a buffer die, an intermediate core die stack stacked on the buffer die, the intermediate core die stack including a plurality of intermediate core dies and a gap filling portion covering outer surfaces of the plurality of intermediate core dies, and a top core die stack stacked on the intermediate core die stack, the top core die stack including a top core die and a flexibility compensating portion covering an outer surface of the top core die. Each of the plurality of intermediate core dies includes a substrate, a front insulating layer provided on a front surface of the substrate, a first bonding pad provided in the front insulating layer, a backside insulating layer provided on a backside surface of the substrate, and a second bonding pad provided in the backside insulating layer. The gap filling portion and the flexibility compensating portion are directly bonded to each other.

According to example embodiments, a semiconductor package includes a buffer die, an intermediate core die stack stacked on the buffer die, and a top core die stack stacked on the intermediate core die stack. The intermediate core die stack includes a plurality of intermediate core dies stacked on one another and a gap filling portion covering outer surfaces of the intermediate core dies. The top core die stack includes a top core die and a flexibility compensating portion covering an outer surface of the top core die. Each of the plurality of intermediate core dies includes a substrate, a front insulating layer provided on a front surface of the substrate, a first bonding pad provided in the front insulating layer, a backside insulating layer provided on a backside surface of the substrate, and a second bonding pad provided in the backside insulating layer.

According to example embodiments, in a method of manufacturing a semiconductor package, a wafer including a buffer die formed therein is provided. A first reconstructed wafer including a plurality of intermediate core dies and a first gap filling portion that covers outer surfaces of the plurality of intermediate core dies is formed on the wafer. A second reconstructed wafer including a top core die and a second gap filling portion that covers an outer surface of the top core die is formed on a carrier substrate. The second reconstructed wafer is stacked on the first reconstructed wafer. The first gap filling portion and the second gap filling portion are directly bonded to each other.

According to example embodiments, a semiconductor package may include an intermediate core die stack and a top core die stack sequentially stacked on a buffer die. The intermediate core die stack may include a plurality of intermediate core dies and a first gap filling portion that covers outer surfaces of the intermediate core dies. The top core die stack may include a top core die and a second gap filling portion as a flexibility compensating portion that covers an outer surface of the top core die.

The intermediate core die stack and the top core die stack may be bonded to each other by hybrid bonding. The first gap filling portion of the intermediate core die stack may be directly bonded to the second gap filling portion of the top core die stack. The first and second gap filling portions may include an inorganic dielectric layer or an organic dielectric layer. The first and second gap filling portions may be directly bonded to each other to form a bonding interface layer.

A second reconstructed wafer including the top core die and the second gap filling portion may be bonded to a first reconstructed wafer including the intermediate core die stack by wafer-to-wafer bonding. Accordingly, voids may be prevented from occurring at a bonding interface of the relatively thick top core die to thereby improve bonding quality.

### BRIEF DESCRIPTION OF THE DRAWINGS

Example embodiments will be more clearly understood from the following detailed description taken in conjunction with the accompanying drawings. FIGS. 1 to 31 represent non-limiting, example embodiments as described herein.

FIG. 1 is a cross-sectional view illustrating a semiconductor package according to example embodiments.

FIG. 2 is an enlarged cross-sectional view illustrating portion ‘A’ in FIG. 1.

FIG. 3 is an enlarged cross-sectional view illustrating portion ‘B’ in FIG. 1.

FIG. 4 is an enlarged cross-sectional view illustrating portion ‘C’ in FIG. 1.

FIGS. 5 to 21 are views illustrating a method of manufacturing a semiconductor package according to example embodiments.

FIG. 22 is a cross-sectional view illustrating a semiconductor package according to example embodiments.

FIG. 23 is an enlarged cross-sectional view illustrating portion ‘I’ in FIG. 22.

FIGS. 24 to 26 are views illustrating a method of manufacturing a semiconductor package according to example embodiments.

FIG. 27 is a cross-sectional view illustrating a semiconductor package according to example embodiments.

FIGS. 28 to 31 are views illustrating a method of manufacturing a semiconductor package according to example embodiments.

### DETAILED DESCRIPTION OF EXAMPLE EMBODIMENTS

Hereinafter, example embodiments will be explained in detail with reference to the accompanying drawings.

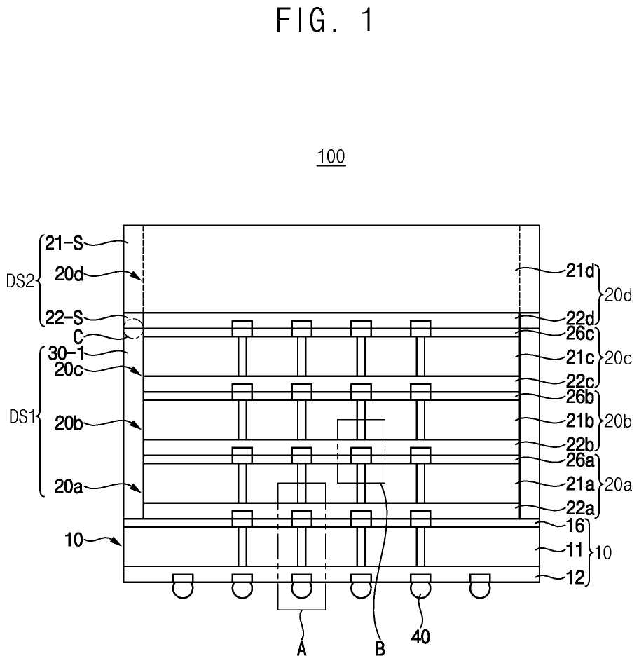

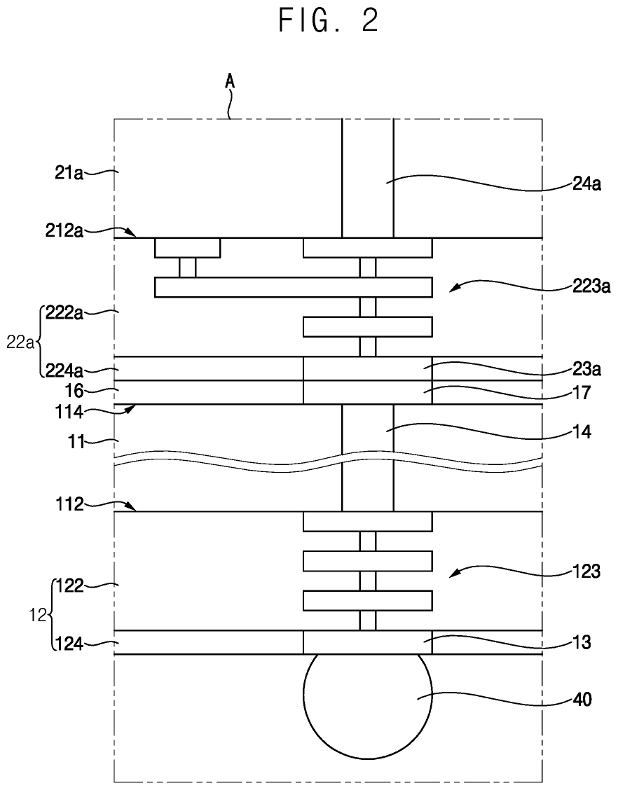

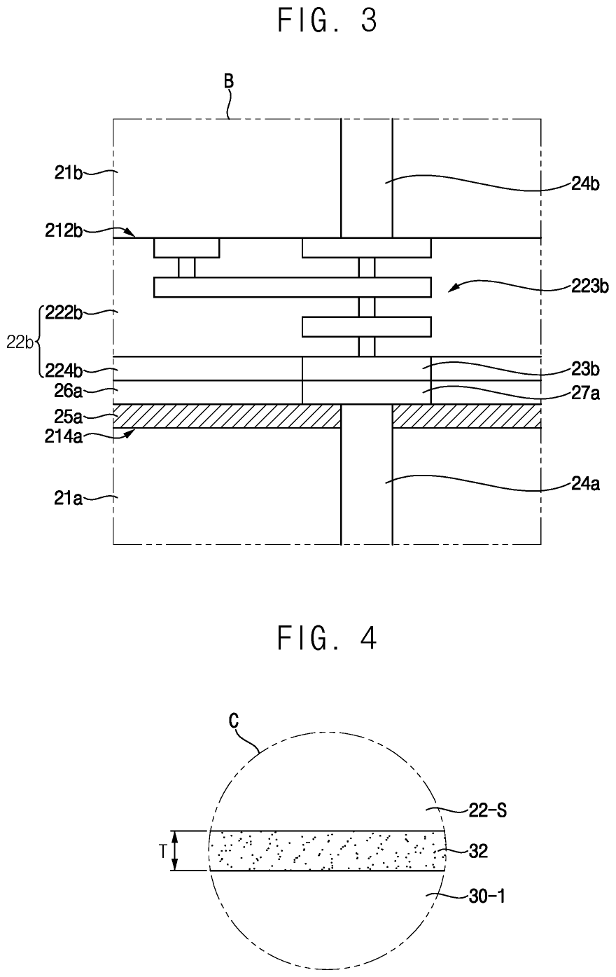

FIG. 1 is a cross-sectional view illustrating a semiconductor package according to example embodiments. FIG. 2 is an enlarged cross-sectional view illustrating portion ‘A’ in FIG. 1. FIG. 3 is an enlarged cross-sectional view illustrating portion ‘B’ in FIG. 1. FIG. 4 is an enlarged cross-sectional view illustrating portion ‘C’ in FIG. 1.

Referring to FIGS. 1 to 4, a semiconductor package 100 may include semiconductor chips (dies) 20 (20a to 20d) stacked therein. The semiconductor package 100 may include a buffer die 10, and an intermediate core die stack DS1 and a top core die stack DS2 sequentially stacked on the buffer die 10.

A plurality of semiconductor chips (dies) 20a, 20b, 20c and 20d may be stacked vertically. In this embodiment, the semiconductor chips (dies) 20a, 20b, 20d and 20d may be the same as, substantially the same as or similar to each other. Accordingly, the same or like reference numerals will be used to refer to the same or like elements and repeated descriptions of the same elements may be omitted.

In this embodiment, the semiconductor package as a multi-chip package is illustrated as including four stacked semiconductor chips 20a, 20b, 20c and 20d on the buffer die 10, however, embodiments of the present disclosure are not limited thereto. For example, the semiconductor package may include 8, 12, or 16 stacked semiconductor chips.

Each of the semiconductor chips 20a, 20b, 20c and 20d may include or may be an integrated circuit chip completed by performing semiconductor manufacturing processes. Each semiconductor chip may include or may be, for example, a memory chip or a logic chip. The semiconductor package 100 may include or may be a memory device. The memory device may include or may be a high bandwidth memory (HBM) device.

In example embodiments, a buffer die 10 may include a substrate 11, a front insulating layer 12, a plurality of first bonding pads 13, a plurality of through electrodes 14, and a backside insulating layer 16, and a plurality of second bonding pads 17. Additionally, the buffer die 10 may further include conductive bumps 40 as conductive connection members respectively provided on the first bonding pads 13. The buffer die 10 may be mounted on a package substrate or an interposer via the conductive bumps 40. For example, each conductive bump 40 may include or may be a solder bump. Alternatively, each conductive bump 40 may include or be formed of a pillar bump and a solder bump formed on the pillar bump.

The substrate 11 may have a first surface 112 and a second surface 114 opposite to the first surface 112. The first surface 112 may be an active surface, and the second surface 114 may be a non-active surface. Circuit patterns may be provided on the first surface 112 of the substrate 11. The first surface 112 may be referred to as a front surface on which the circuit patterns are formed, and the second surface may be referred to as a backside surface.

For example, the substrate 11 may be a single crystal silicon substrate. The circuit patterns may include transistors, capacitors, diodes, etc. The circuit patterns may constitute circuit elements. Accordingly, the buffer die 10 may be a semiconductor device having a plurality of circuit elements formed therein.

As illustrated in FIG. 2, the front insulating layer 12 as an insulation interlayer may be formed on the first surface 112 of the substrate 11, that is, the front surface. The front insulating layer 12 may include a plurality of insulating layers 122 and 124 and wirings 123 in the insulating layers. Additionally, the first bonding pads 13 may be provided in an outermost insulating layer (e.g., the lowermost insulating layer in FIG. 2) of the front insulating layer 12. For example, the first bonding pads 13 may be at the same level as the outermost insulating layer 124 of the front insulating layer 12.

For example, the front insulating layer 12 may include a metal wiring layer 122 and a first passivation layer 124. The metal wiring layer 122 may include a plurality of wirings 123 therein. For example, the metal wiring layer 122 may include a metal interconnection structure including a plurality of wirings 123 vertically stacked in buffer layers and/or insulating layers. For example, the metal wiring layer 122 may include a plurality of buffer layers and/or a plurality of insulating layers stacked in a vertical direction. For example, the buffer layers and the insulating layers may be formed of dielectric materials, and may be collectively referred to as dielectric layers. The first bonding pads 13 may be formed on an uppermost wiring (e.g., below the lowermost wiring in FIG. 2) among the plurality of wirings 123. For example, the wirings may include or be formed of aluminum (Al), copper (Cu), tin (Sn), nickel (Ni), gold (Au), platinum (Pt), or alloys thereof.

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

As used herein, the singular forms “a”, “an” and “the” are intended to include the plural forms as well, unless the context clearly indicates otherwise. As used herein, the term “and/or” includes any and all combinations of one or more of the associated listed items and may be abbreviated as “/”.

The first passivation layer 124 may be formed on the metal wiring layer 122 and at least a portion of a first bonding pad 13 may be exposed from the first passivation layer 124. The first passivation layer 124 may include a plurality of stacked insulating layers. For example, the first passivation layer 124 may include a first protective layer including or formed of an oxide layer and a second protective layer including or formed of a nitride layer, sequentially stacked. The first protective layer may include or be formed of silicon oxide, and the second protective layer may include or be formed of silicon nitride or silicon carbonitride.

The first bonding pad 13 may be provided in the first passivation layer 124. The first bonding pad 13 may be exposed through an outer surface of the first passivation layer 124. Although not illustrated in the figures, an insulation interlayer may be provided on the first surface 112 of the substrate 11 to cover the circuit patterns. The insulation interlayer may be formed of or include, for example, silicon oxide or a low dielectric material. The insulation interlayer may include lower wiring therein, which is electrically connected to the circuit patterns. Accordingly, the circuit pattern may be electrically connected to the first bonding pad 13 by the lower wirings and the wirings.

A through electrode (through silicon via, TSV) 14 may vertically penetrate the insulation interlayer and/or extend from the first surface 112 to the second surface 114 of the substrate 11. The through electrode 14 may contact a lowermost wiring (e.g., the uppermost wiring in FIG. 2) of the metal wiring structure. Accordingly, the through electrode 24 may be electrically connected to the first bonding pad 13 by the wirings 123.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element, there are no intervening elements present at the point of contact. Other words used to describe the relationship between elements should be interpreted in a like fashion (e.g., “between” versus “directly between,” “adjacent” versus “directly adjacent,” etc.).

As used herein, components described as being “electrically connected” are configured such that an electrical signal can be transferred from one component to the other (although such electrical signal may be attenuated in strength as it transferred and may be selectively transferred).

The backside insulating layer 16 may be formed on the second surface 114 of the substrate 11, that is, the backside surface. A second bonding pad 17 may be provided in the backside insulating layer 16. For example, the second bonding pad 17 may be disposed on an exposed surface of the through electrode 14. The backside insulating layer 16 may include silicon oxide, carbon-doped silicon oxide, silicon carbonitride (SiCN), etc. Accordingly, the first and second bonding pads 13 and 17 may be electrically connected to each other by the through electrode 24

In example embodiments, the intermediate core die stack DS1 may include a plurality of intermediate cores 20a, 20b and 20c and a first gap filling portion 30-1 that covers/contacts outer surfaces of the intermediate core dies 20a, 20b, and 20c. Each of the intermediate core dies 20 (e.g., 20a, 20b, and 20c) may include a substrate 21 (e.g., 21a, 21b, or 21c), a front insulating layer 22 (e.g., 22a, 22b, or 22c) provided on a front surface of the substrate 21 and in which a first bonding pad 23 (e.g., 23a, 23b, or 23c) is provided, and a backside insulating layer 26 (e.g., 26a, 26b, or 26c) provided on a backside surface of the substrate 21 and in which a second bonding pad 27 (e.g., 27a, 27b, or 27c) is provided. In addition, at least one intermediate core die 20 may further include a through electrode 24 (e.g., 24a, 24b, or 24c) that penetrates the substrate 21 and is electrically connected to the first and second bonding pads 23 and 27.

For example, the intermediate core die stack DS1 may be bonded onto the buffer die 10. The intermediate core die stack DS1 may include the intermediate core dies 20a, 20b, and 20c stacked in three stages and the first gap filling portion 30-1 covering/contacting the outer surfaces of the intermediate core dies 20a, 20b, and 20c. For example, the intermediate core dies 20a, 20b, and 20c may be stacked in a vertical direction to form three layers of core dies in the vertical direction. In this embodiment, the intermediate core die stack DS1 may include, but is not limited to, intermediate core dies 20a, 20b and 20c stacked in three stages (e.g., three layers). For example, the intermediate core die stack DS1 may include 7, 11, or 15 intermediate core dies stacked in 7, 11, or 15 stages/layers, or another number of core dies in certain embodiments.

As illustrated in FIGS. 2 and 3, a first-stage intermediate core die 20a of the intermediate core die stack DS1 may include a substrate 21a, a front insulating layer 22a, and a plurality of first bonding pads 23a, a plurality of through electrodes 24a, a backside insulating layer 26a and a plurality of second bonding pads 27a.

The substrate 21a may have a first surface 212a and a second surface 214a opposite to the first surface 212a. The first surface 212a may be an active surface, and the second surface 214a may be a non-active surface. Circuit patterns may be provided on the first surface 212a of the substrate 21a. The front insulating layer 22a as an insulation interlayer may be formed on the first surface 212a of the substrate 21a, that is, a front surface. The front insulating layer 22a may include a plurality of insulating layers 222a and 224a, and wirings 223a may be formed in the insulating layers 222a and 224a. Additionally, the first bonding pad 23a may be provided in an outermost insulating layer of the front insulating layer 22a. For example, the front insulating layer 22a may include a first insulating layer 222a and a first passivation layer 224a. A plurality of wirings 223a may be formed in the first insulating layer 222a.

The through electrode 24a may vertically extend from the first surface 212a to the second surface 214a of the substrate 21a. The through electrode 24a may be electrically connected to the first bonding pad 23a by the wirings 223a. The backside insulating layer 26a may be formed on the second surface 214a of the substrate 21a, that is, a backside surface. The second bonding pad 27a may be provided in the backside insulating layer 26a. Accordingly, the first and second bonding pads 23a and 27a may be electrically connected to each other by the through electrode 24a.

Similarly, a second-stage intermediate core die 20b of the intermediate core die stack DS1 may include a substrate 21b, a front insulating layer 22b, a plurality of first bonding pads 23b, a plurality of through electrodes 24b, a backside insulating layer 26b, and a plurality of second bonding pads 27b. Since the core dies 20a, 20b, 20c and 20d are the same as, substantially the same as or similar to each other, the same or like reference numerals will be used to refer to the same or like elements and repeated descriptions of the same elements may be omitted.

As illustrated in FIG. 2, the first-stage intermediate core die 20a and the buffer die 10 may be bonded to each other by hybrid bonding. The second bonding pad 17 of the buffer die 10 and the first bonding pad 23a of the first-stage intermediate core die 20a may be bonded to each other by copper-copper hybrid bonding (Cu-Cu Hybrid Bonding). The front surface of the first-stage intermediate core die 20a, e.g., the front insulating layer 22a on the first surface 212a of the substrate 21a may be directly bonded to the backside insulating layer 16 on the substrate 11 of the buffer die 10.

As used herein, two layers directly bonded to each other may be layers bonded to each other without any additional material layer between the two layers. For example, two directly bonded layers may not use adhesives between the two bonded layers and the two layers are bonded to each other by a chemical force and/or a mechanical force, e.g., by an attraction force, a bonding force, and/or a binding force.

As illustrated in FIG. 3, the second-stage intermediate core die 20b and the first-stage intermediate core die 20a may be bonded to each other by hybrid bonding. The second bonding pad 27a of the first-stage intermediate core die 20a and the first bonding pad 23b of the second-stage intermediate core die 20b may be bonded to each other by copper-copper hybrid bonding (Cu—Cu Hybrid Bonding).

The front insulating layer 22b on the front surface of the second-stage intermediate core die 20b may be directly bonded to the backside insulating layer 26a on the backside surface of the first-stage intermediate core die 20a. The outermost insulating layers of the backside insulating layer 26a and the front insulating layer 22b may include an insulating material that contacts each other and provides excellent bonding strength, thereby providing a bonding structure. The backside insulating layer 26a and the front insulating layer 22b may be bonded to each other by a high temperature annealing process while in contact with each other. Here, the bonding structure may have a relatively strong bonding strength by covalent bonding.

Similarly, a third-stage intermediate core die 20c and the second-stage intermediate core die 20b may be bonded to each other by hybrid bonding. The second bonding pad 27b of the second-stage intermediate core die 20b and a first bonding pad 23c of the third-stage intermediate core die 20c may be bonded to each other by copper-copper hybrid bonding (Cu—Cu Hybrid Bonding). A front insulating layer 22c on the front surface of the third-stage intermediate core die 20c may be directly bonded to the backside insulating layer 26b on the backside surface of the second-stage intermediate core die 20b.

The first gap filling portion 30-1 may be provided to cover the outer surfaces of the intermediate core dies 20a, 20b and 20c stacked in three stages on the buffer die 10. For example, the first gap filling portion 30-1 may be formed by a conformal deposition process such as an atomic layer deposition (ALD) process or a chemical vapor deposition (CVD) process. The first gap filling portion may include or may be an inorganic dielectric layer or an organic dielectric layer. The inorganic dielectric layer may include or be formed of silicon oxide, silicon oxynitride, phosphosilicate glass (PSG), boro-phosphosilicate glass (BPSG), etc. The organic dielectric layer may include or be formed of a polymer or the like.

In example embodiments, the top core die stack DS2 may be bonded onto the intermediate core die stack DS1. The top core die stack DS2 may include a top core die 20d stacked in one stage (e.g., one layer) and a second gap filling portion covering an outer surface of the top core die 20d. The top core die stack DS2 may be stacked on the intermediate core die stack DS1. A thickness of the top core die 20d may be greater than each of thicknesses of the intermediate core dies 20a, 20b, and 20c. The thickness of the top core die 20d may be in a range of 100 μm to 300 μm. The thicknesses of the intermediate core dies 20a, 20b, and 20c may be in a range of 20 μm to 50 μm. The thicknesses of the core dies may be distances between bottom surfaces and top surfaces in a vertical direction.

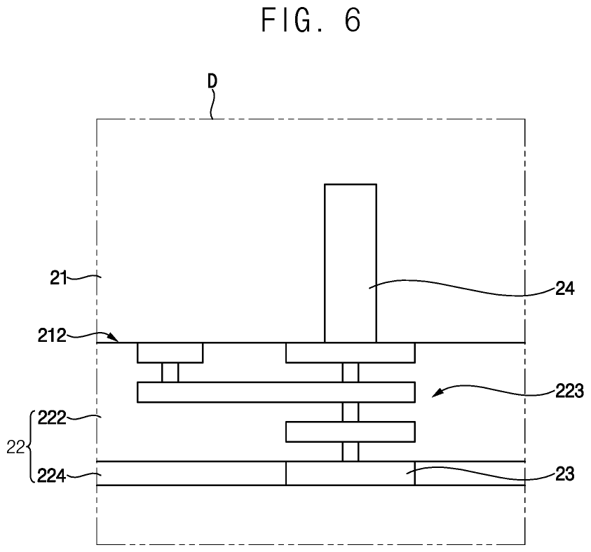

In example embodiments, the second gap filling portion may be provided to cover/contact the outer surface of the top core die 20d. The top core die 20d may include a first substrate region 21d and a first front insulating layer region 22d provided on the first substrate region 21d. The second gap filling portion may include a second substrate region 21-S surrounding the first substrate region 21d and a second front insulating layer region 22-S provided on the second substrate region 21-S and surrounding the first front insulating layer region 22d. The first and second front insulating layer regions 22d and 22-S may include a front insulating layer 22 (see FIG. 6). The front insulating layer 22 may include a first passivation layer provided in an outermost (e.g., a lowermost) insulating layer thereof. The first passivation layer may include or be formed of silicon oxide, silicon nitride, or silicon carbonitride.

The top core die 20d of the top core die stack DS2 and the intermediate core die 20c of the intermediate core die stack DS1 may be bonded to each other by hybrid bonding. The first front insulating layer 22d on a front surface of the top core die 20d may be directly bonded to a backside insulating layer 26c on a backside surface of the intermediate core die 20c, and a second bonding pad 27c of the intermediate core die 20c and a first bonding pads 23d of the top core die 20d may be bonded to each other by copper-copper hybrid bonding.

As illustrated in FIG. 4, when the top core die stack DS2 and the intermediate core die stack DS1 are bonded to each other, the second gap filling portion of the top core die stack DS2 and the first gap fill filling portion 30-1 of the first core die stack DS1 may be bonded to each other by a thermal compression process and an annealing process. By the annealing process, the first gap filling portion 30-1 and the second front insulating layer region 22-S (i.e., first passivation layer) of the second gap filling portion may be directly bonded to each other to form a bonding interface layer 32. The bonding interface layer 32 may have a thickness (T) in a range of 2 Å to 500 Å. The bonding interface layer may include or be formed of silicon oxide. The bonding interface layer may be detected by a transmission electron microscope (TEM).

As used herein, a bonding interface layer of two directly bonded layers may be a layer of chemical combination between materials of the two directly bonded layers.

In example embodiments, a width of buffer die 10 may be the same as a width of intermediate core die stack DS1. The width of the intermediate core die stack DS1 may be the same as a width of the top core die stack DS2. The width of the buffer die 10 may be the same as the width of the top core die stack DS2. The widths may be distances between opposite side surfaces in a horizontal direction (e.g., in a direction perpendicular to the side surfaces of the buffer die 10, the intermediate core die stack DS1 and the top core die stack DS2).

An outer surface of the buffer die 10 and an outer surface of the intermediate core die stack DS1 may be positioned on the same plane. An outer surface of the substrate 11 of the buffer die 10 may be coplanar with an outer surface of the first gap filling portion 30-1 of the intermediate core die stack DS1.

The outer surface of the intermediate core die stack DS1 and the outer surface of the top core die stack DS2 may be positioned on the same plane. The outer surface of the first gap filling portion 30-1 of the intermediate core die stack DS1 may be coplanar with an outer surface of the second front insulating layer region 22-S of the top core die stack DS2.

As mentioned above, the semiconductor package 100 may include the intermediate core die stack DS1 and the top core die stack DS2 sequentially stacked on the buffer die 10. The intermediate core die stack DS1 may include the plurality of intermediate core dies 20a, 20b, and 20c and the first gap filling portion 30 covering/contacting the outer surfaces of the intermediate core dies 20a, 20b, and 20c. The top core die stack DS2 may include the top core die 20d and the second gap filling portion as a flexibility compensating portion that covers the outer surface of the top core die 20d.

The intermediate core die stack DS1 and the top core die stack DS2 may be bonded to each other by hybrid bonding. The first gap filling portion 30-1 of the intermediate core die stack DS1 and the second gap filling portion of the top core die stack DS2 may be directly bonded to each other. The first and second gap filling portions may include or may be an inorganic dielectric layer or an organic dielectric layer. The first and second gap filling portions may be directly bonded to each other to form the bonding interface layer 32.

A second reconstructed wafer including the top core die stack (the top core die 20d and the second gap filling portion) may be bonded to a first reconstructed wafer including the intermediate core die stack DS1 by wafer-to-wafer bonding. The second gap filling portion including the second substrate region 21-S and the second front insulating layer region 22-S may function as the flexibility compensating portion. For example, during the wafer-to-wafer bonding, the second reconstructed wafer may be brought into contact with the first reconstructed wafer while the center portion of the second reconstructed wafer is deformed to be convex downwards. Bonding may be initiated after the central portion of the second reconstructed wafer and the central portion of the first reconstructed wafer first contact each other. Accordingly, voids may be prevented from occurring at the bonding interface of the top core die 20d to thereby improve the bonding quality.

Hereinafter, a method of manufacturing the semiconductor package of FIG. 1 will be described. A case where the semiconductor package includes a high bandwidth memory (HBM) device will be described. However, it will be understood that a method of manufacturing a semiconductor package according to example embodiments is not limited thereto.

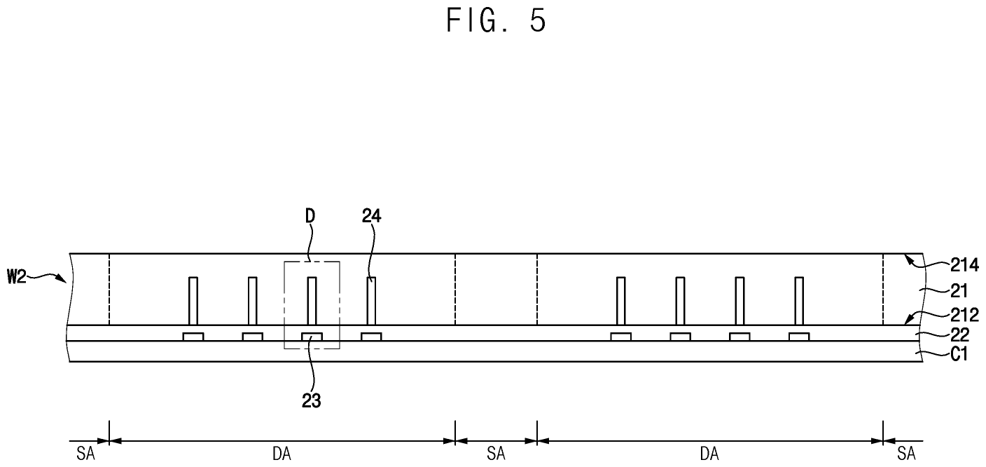

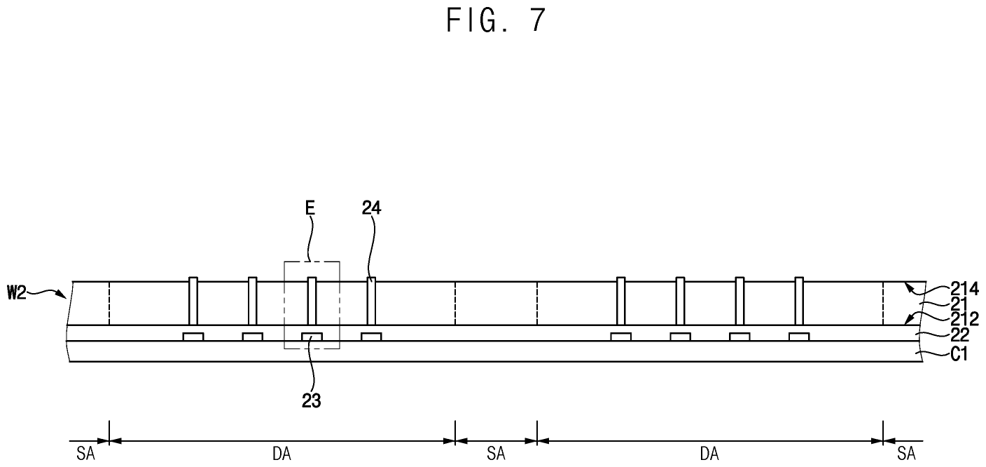

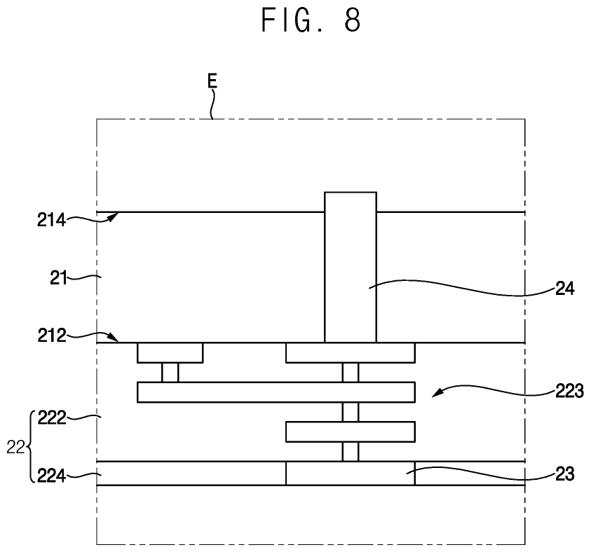

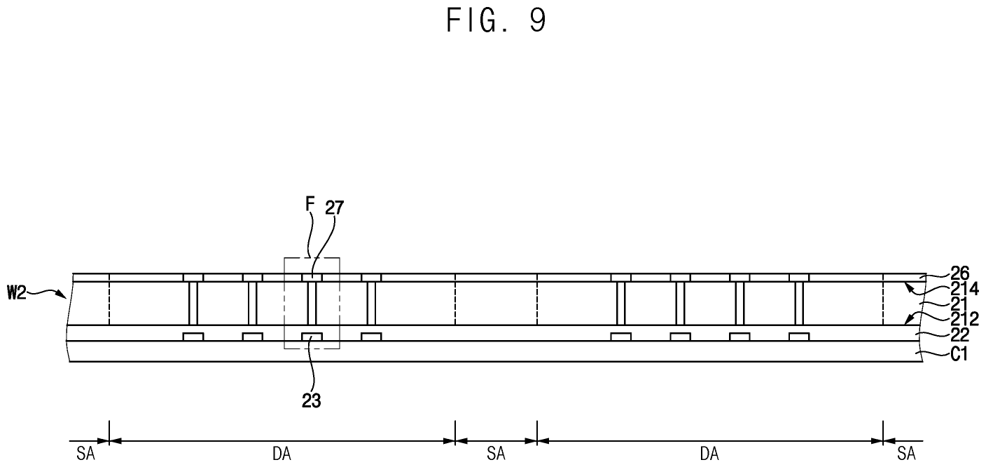

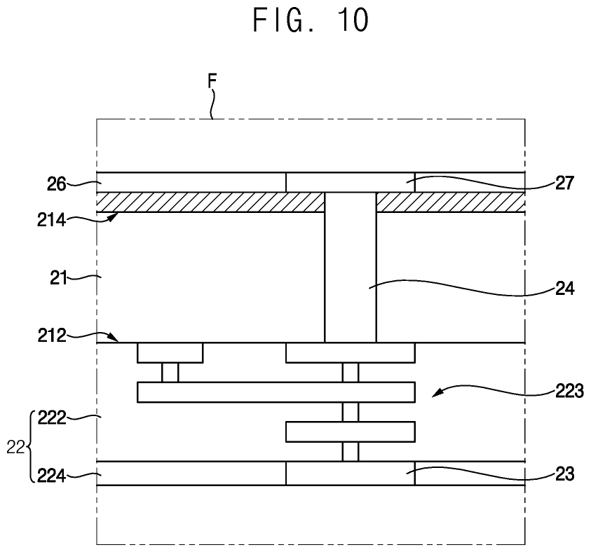

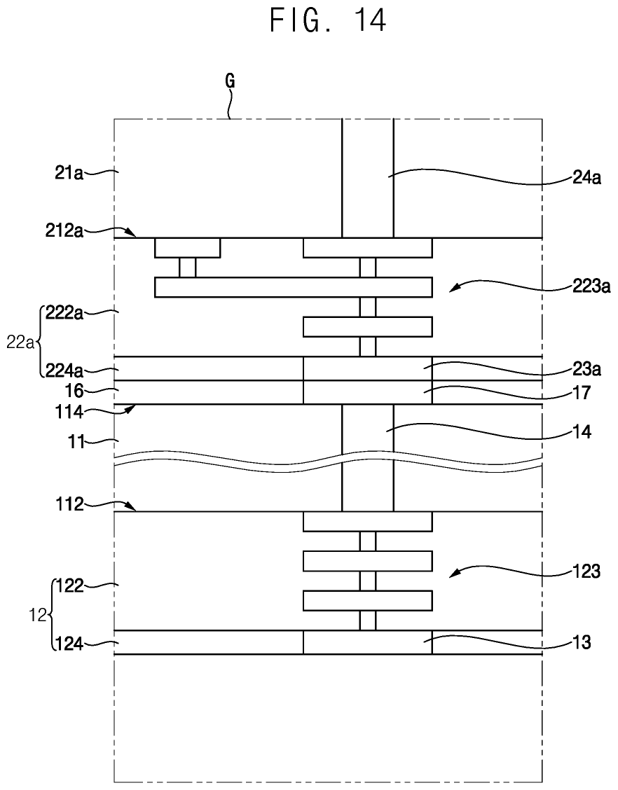

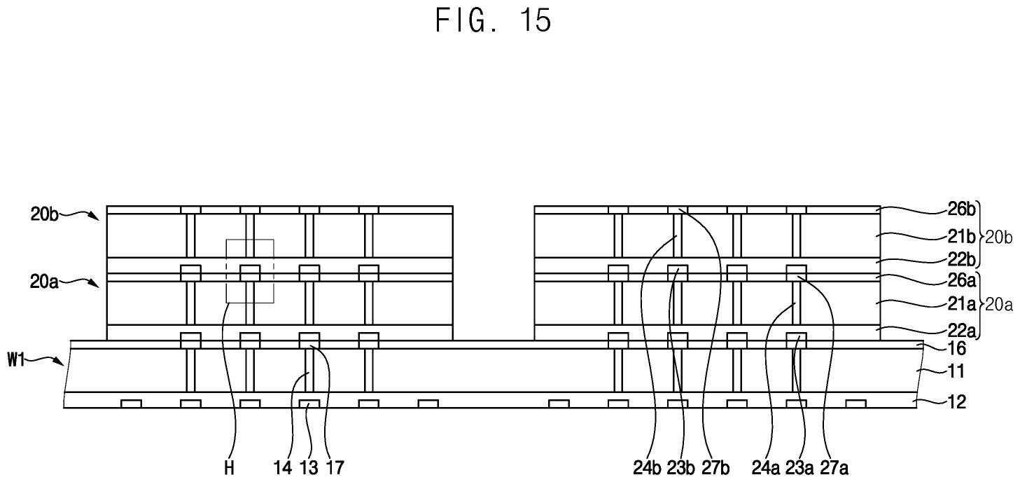

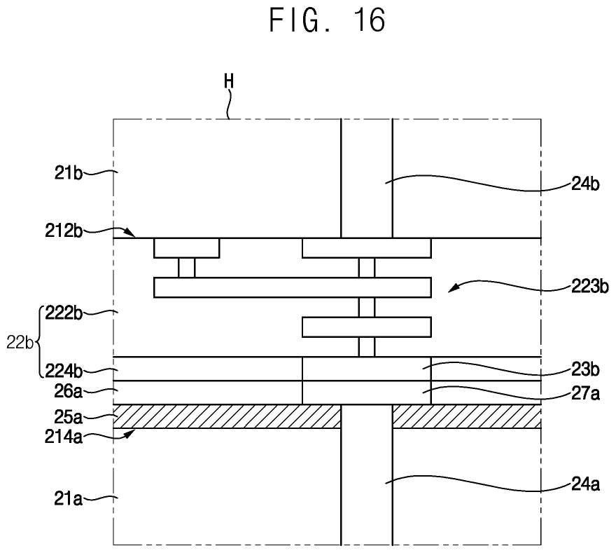

FIGS. 5 to 21 are views illustrating a method of manufacturing a semiconductor package according to example embodiments. FIG. 6 is an enlarged cross-sectional view illustrating portion ‘D’ in FIG. 5. FIG. 8 is an enlarged cross-sectional view illustrating portion ‘E’ in FIG. 7. FIG. 10 is an enlarged cross-sectional view illustrating portion ‘F’ in FIG. 9. FIG. 14 is an enlarged cross-sectional view illustrating portion ‘G’ in FIG. 13. FIG. 16 is an enlarged cross-sectional view illustrating portion ‘H’ in FIG. 15.

Referring to FIGS. 5 to 12, first, a second wafer W2 may be individualized into semiconductor chips (core dies) 20.

As illustrated in FIGS. 5 and 6, the second wafer W2 including a plurality of semiconductor chips (core dies) formed therein may be prepared.

In example embodiments, the second wafer W2 may include a substrate 21 and a front insulating layer 22 having a first bonding pad 23 that is provided in an outer surface thereof. Additionally, the second wafer W2 may include a plurality of through electrodes 24 that are provided in the substrate 21 and are electrically connected to the first bonding pads 23.

The substrate 21 may have a first surface 212 and a second surface 214 opposite to each other. The substrate 21 may include a die region DA where circuit patterns and cells are formed and a scribe lane region SA surrounding the die region DA. The substrate 21 may be cut along the scribe lane region SA that divides the plurality of die regions DA of the second wafer W2 by a following dicing process to form individualized semiconductor chips.

For example, the substrate 21 may include silicon, germanium, silicon-germanium, or III-V compounds, e.g., GaP, GaAs, GaSb, etc. In some embodiments, the second substrate 21 may be a silicon-on-insulator (SOI) substrate, or a germanium-on-insulator (GOI) substrate.

The circuit patterns may include transistors, capacitors, diodes, etc. The circuit patterns may constitute circuit elements. Accordingly, the semiconductor chip may be a semiconductor device with a plurality of the circuit elements formed therein. The circuit patterns may be formed on the first surface 212 of the substrate 21 by performing a FEOL (Front End of Line) process for manufacturing semiconductor devices. The surface of the substrate on which the FEOL process is performed may be referred to as a front surface of the substrate, and a surface opposite to the front surface may be referred to as a backside surface.

The circuit element may include a plurality of memory devices. Examples of the memory devices include a volatile semiconductor memory device and a non-volatile semiconductor memory device. Examples of the volatile semiconductor memory device may be DRAM, SRAM, etc. Examples of the non-volatile semiconductor memory devices may be EPROM, EEPROM, Flash EEPROM, etc.

The front insulating layer 22 may be formed as an insulation interlayer on the first surface 212 of the substrate 21, that is, the front surface. The front insulating layer 22 may include a plurality of insulating layers 222 and 224, and wirings 223 may be formed in the insulating layers. Additionally, the first bonding pad 23 may be provided in the outermost insulating layer of the front insulating layer 22.

As illustrated in FIG. 6, for example, the front insulating layer 22 may include a first insulating layer 222 and a first passivation layer 224.

In the first insulating layer 222, the plurality of wirings 223 may be formed. For example, a metal wiring structure including the plurality of wirings 223 may be vertically stacked in buffer layers and/or insulating layers. For example, the first insulating layer 222 may include a plurality of buffer layers and/or a plurality of insulating layers stacked in a vertical direction. For example, the buffer layers and the insulating layers may be formed of dielectric materials, and may be collectively referred to as dielectric layers. The first bonding pad 23 may be formed on an uppermost wiring among the plurality of wirings 223. For example, the wirings may include or be formed of aluminum (Al), copper (Cu), tin (Sn), nickel (Ni), gold (Au), platinum (Pt), or alloys thereof.

The first passivation layer 224 may be formed on the first insulating layer 222 and may expose at least a portion of the first bonding pad 23. The first passivation layer 224 may include a plurality of stacked insulating layers. For example, the first passivation layer 224 may include a first protective layer including an oxide layer and a second protective layer including a nitride layer, sequentially stacked. The first protective layer may include or be formed of silicon oxide, and the second protective layer may include or be formed of silicon nitride or silicon carbonitride.

The first bonding pad 23 may be provided in the first passivation layer 224. The first bonding pad 23 may be exposed through an outer surface of the first passivation layer 224. Although not illustrated in the figures, an insulation interlayer may be provided on the first surface 212 of the substrate 21 to cover the circuit patterns. The insulation interlayer may be formed to include, for example, silicon oxide or a low dielectric material. The insulation interlayer may include lower wiring therein, which are electrically connected to the circuit patterns. Accordingly, the circuit pattern may be electrically connected to the first bonding pad 23 by the lower wirings and the wirings.

The through electrode (through silicon via, TSV) 24 may vertically penetrate the insulation interlayer and extend (e.g., vertically and lengthwise) from the first surface 212 of the substrate 21 to a predetermined depth. The through electrode 24 may contact a lowermost wiring (e.g., an uppermost wiring in FIG. 6) of the metal wiring structure. Accordingly, the through electrode 24 may be electrically connected to the first bonding pad 23 by the wirings 223.

A liner layer (not illustrated) may be provided on an outer surface of the through electrode 24. The liner layer may include or be formed of silicon oxide or carbon-doped silicon oxide. The liner layer may electrically insulate the through electrode 24 from the substrate 21 and the first insulating layer 222.

The through electrode 24 and the first bonding pad 23 may include or be formed of the same metal. For example, the metal may include or may be copper (Cu). However, embodiments are not limited thereto, and the through electrode and the first bonding pad may include or be formed of a material (e.g., gold (Au)) that can be bonded by inter-diffusion of metals by a high-temperature annealing process.

As illustrated in FIGS. 7 and 8, the second surface 214 of the substrate 21 may be partially removed to expose one end portion of the through electrode 24. For example, a portion of the substrate 21 may be removed from the second surface 214 to expose a portion of the through electrodes 24.

In example embodiments, the substrate 21 may be partially removed from the second surface 214 using a substrate support system (WSS). First, the second wafer (W2) may be attached to a carrier substrate (C1) using an adhesive film, and then, the substrate 21 may be partially removed from the second surface 214 until the end portion of the through electrode 24 is exposed.

For example, a grinding process such as a back lap process may be performed to partially remove the substrate 21, and then an etching process such as a silicon recess process may be performed to expose the end portion of the through electrode 24. Accordingly, a thickness of the substrate 21 may be reduced to a desired thickness. For example, the substrate 21 may have a thickness in a range of about 20 μm to about 50 μm.

Terms such as “about” or “approximately” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range.

In the back lap process, the entire backside surface of the second wafer W2 may be ground. In the silicon recess process, only the silicon in the backside surface of the second wafer W2 may be selectively etched. The etching process may be an isotropic dry etching process. The etching process may include a plasma etching process, etc. The plasma etching process may be performed using inductively coupled plasma, capacitively coupled plasma, microwave plasma, etc.

Since the grinding process and the etching process are performed in the wafer level, the entire second surface 214 of the substrate 21 may be reduced for the substrate 21 to have a uniform thickness. Accordingly, the end portions of the through electrodes 24 may protrude uniformly from the second surface 214 of the substrate 21 over the entire second surface 214 of the substrate 21 to have same heights.

As illustrated in FIGS. 9 and 10, a backside insulating layer 26 having a second bonding pad 27 in an outer surface thereof may be formed on the second surface 214 of the substrate 21.

For example, an etch stop layer may be formed on the second surface 214 of the substrate 21, and a sacrificial layer may be formed on the etch stop layer. The etch stop layer may be conformally formed to cover the end portions of the through electrodes 24 that protrude from the second surface 214 of the substrate 21. The etch stop layer may cover the entire second surface 214 of the substrate 21. For example, the etch stop layer may have a thickness within a range of 0.1 μm to 1 μm. The etch stop layer may include or be formed of a material that can be used to detect a polishing end point in a subsequent chemical mechanical polishing process. The etch stop layer may include or be formed of a silicon nitride layer. The thickness and material of the etch stop layer may be selected in consideration of a polishing selectivity and polishing conditions in the subsequent chemical mechanical polishing process.

The sacrificial layer may be formed on the etch stop layer to fill a gap (e.g., in a horizontal direction) between the protruding end portions of the through electrodes 24. The sacrificial layer may include or be formed of silicon oxide such as TEOS.

Then, a chemical mechanical polishing (CMP) process using the etch stop layer to detect a polishing end point may be performed to remove the sacrificial layer to expose the end portions of the through electrodes 24. Through the CMP process, the end portions of the through electrodes 24 and portions of the etch stop layer covering them may be removed to form an etch stop layer pattern 25 on the second surface 214 of the substrate 21.

The etch stop layer pattern 25 may expose the end portions of the through electrodes 24. The end portions of the through electrodes 24 may protrudes from the second surface 214 of the substrate 21, and the etch stop layer pattern 25 may cover (e.g., contact) sidewalls of the end portions of the through electrodes 24 that protrude from the second surface 214 of the substrate 210. Accordingly, the upper surfaces of the through electrodes 24 may be exposed by the etch stop layer pattern 25. An upper surface of the etch stop layer pattern 25 and the exposed upper surfaces of the through electrodes 24 may be positioned on the same plane.

Then, the backside insulating layer 26 as a second passivation layer having the second bonding pad 27 that is electrically connected to (e.g., contact) the through electrode 24 may be formed on the etch stop layer pattern 25 on the second surface 214 of the substrate 21.

For example, after the backside insulating layer 26 is formed on the etch stop layer pattern 25 on the second surface 214 of the substrate 21, an opening may be formed in the backside insulating layer 26 to expose the through electrode 24, and a plating process may be performed to form the second bonding pad 27 in the opening of the backside insulating layer 26. The second bonding pad 27 may be disposed on the exposed surface of the through electrode 24. The backside insulating layer 26 may include or be formed of silicon oxide, carbon-doped silicon oxide, and/or silicon carbonitride (SiCN). Accordingly, the first and second bonding pads 23 and 27 may be electrically connected to each other by the through electrode 24.

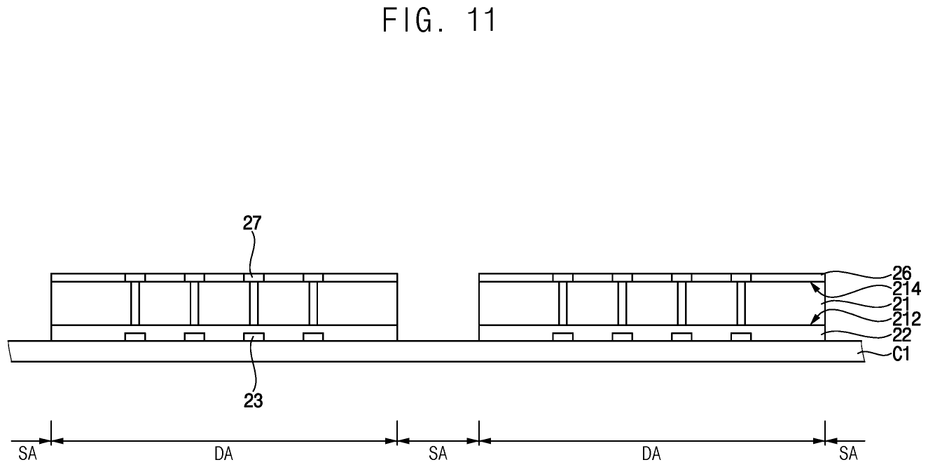

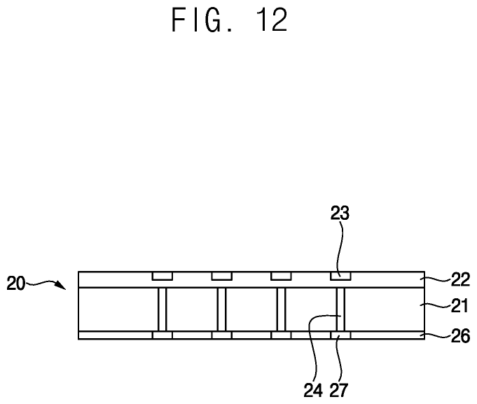

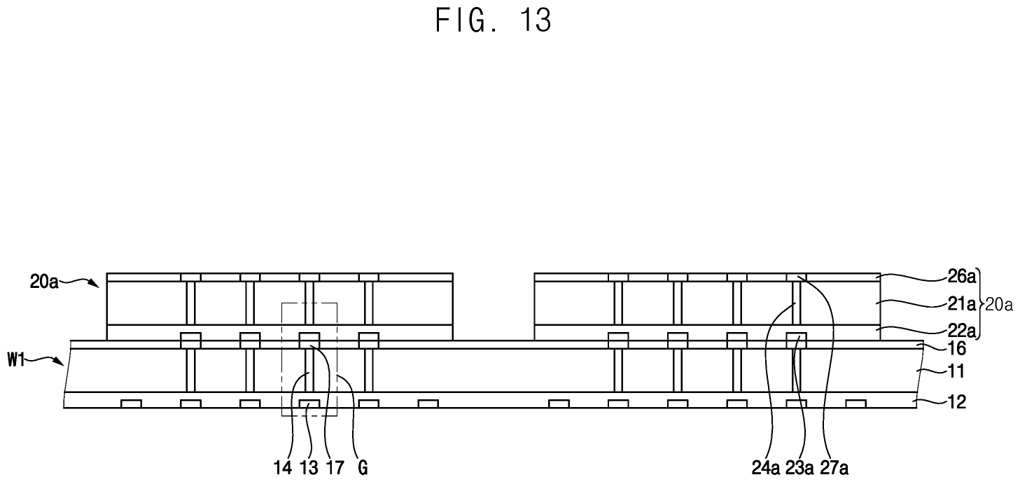

Referring to FIGS. 11 and 12, the second wafer W2 may be cut along the scribe lane region SA to form individual second semiconductor chips (core dies) 20.

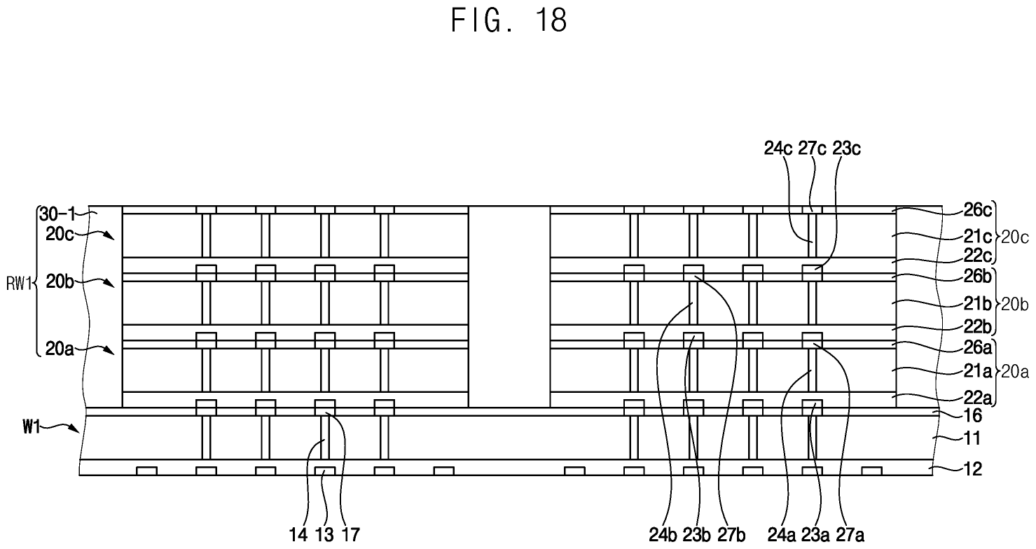

Referring to FIGS. 13 to 18, a first reconstructed wafer RW1 (shown in FIG. 18) including a plurality of intermediate core dies 20a, 20b, 20c and a first gap filling portion 30-1 covering outer surfaces of the plurality of intermediate core dies 20a, 20b, and 20c may be formed on a first wafer W1. In this embodiment, the first reconstructed wafer RW1 may include, but is not limited to, the intermediate core dies 20a, 20b and 20c stacked in three stages (e.g., in three layers).

As illustrated in FIGS. 13 and 14, a plurality of intermediate core dies 20a may be attached in a first stage on the first wafer W1 (die-to-wafer hybrid bonding process).

In example embodiments, the intermediate core dies 20a may be disposed on the first wafer W1 to correspond to die regions DA, e.g., where circuit patterns and cells are formed. Each first-stage intermediate core die 20a may be stacked on the first wafer W1 such that a first surface 212a of a substrate 21a faces the first wafer W1.

A die bonding apparatus may pick up a first-stage intermediate core die 20a individualized through a sawing process and may bond it to the first wafer W1. The die bonding apparatus may attach the first-stage intermediate core die 20a to the first wafer W1 by performing a thermal compression process at a predetermined temperature (for example, about 400° C. or less). By the thermal compression process, the first-stage intermediate core die 20a and the first wafer W1 may be bonded to each other through hybrid bonding. For example, a front surface of the first-stage intermediate core die 20a, e.g., a front insulating layer 22a on the first surface 212a of the substrate 21a may be directly bonded to a backside insulating layer 16 on a substrate 11 of the first wafer W1.

A second bonding pad 17 of the first wafer W1 and a first bonding pad 23a of the first-stage intermediate core die 20a may contact each other. The front surface of the first-stage intermediate core die 20a and a backside surface of the first wafer W1 may be bonded to face each other. When the first wafer W1 and the first-stage intermediate core die 20a are bonded to each other by wafer-to-die bonding, the second bonding pad 17 of the first wafer W1 and the first bonding pads 23a of the first-stage intermediate core die 20a may be bonded to each other by copper-copper hybrid bonding (Cu—Cu Hybrid Bonding).

As illustrated in FIGS. 15 and 16, processes the same as or similar to the processes described with reference to FIGS. 13 and 14 may be performed to attach a plurality of intermediate core dies 20b in a second stage on the plurality of first-stage intermediate core dies 20a on the first wafer W1 (die-to-wafer hybrid bonding process).

Each second-stage intermediate core die 20b may be stacked on a corresponding first-stage intermediate core die 20a such that a front surface of the second-stage intermediate core die 20b faces a backside surface of the corresponding first-stage intermediate core die 20a. By a thermal compression process, the second-stage intermediate core die 20b and the first-stage intermediate core die 20a may be bonded to each other through hybrid bonding. For example, a front insulating layer 22b on the front surface of the second-stage intermediate core die 20b may be directly bonded to a backside insulating layer 26a on the backside of the first-stage intermediate core die 20a. When the first-stage intermediate core die 20a and the second-stage intermediate core die 20b are bonded to each other by die-to-die bonding, a second bonding pad 27a of the first-stage intermediate core die 20a and a first bonding pad 23b of the second-stage intermediate core die 20b may be bonded to each other by copper-copper hybrid bonding.

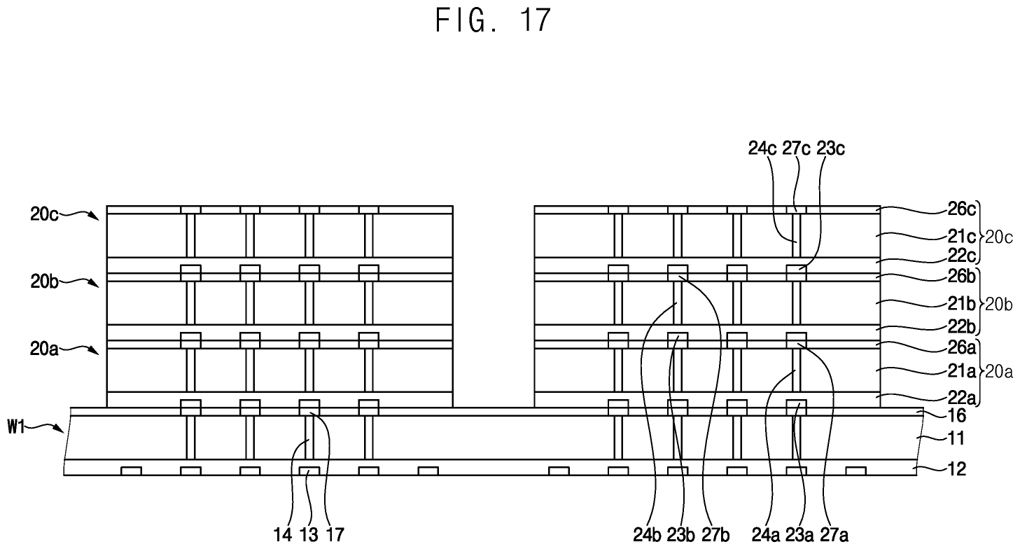

As illustrated in FIG. 17, processes the same as or similar to the processes described with reference to FIGS. 13 and 14 may be performed to attach a plurality of intermediate core dies 20c in a third stage on the second-stage intermediate core dies 20b on the first wafer W1 (die-to-wafer hybrid bonding process).

Each third-stage intermediate core die 20c may be stacked on a corresponding second-stage intermediate core die 20b such that a front surface of the third-stage intermediate core die 20c faces a backside surface of the corresponding second-stage intermediate core die 20b. By a heat compression process, the third-stage intermediate core die 20c and the second-stage intermediate core die 20b may be bonded to each other through hybrid bonding. For example, a front insulating layer 22c on the front surface of the third-stage intermediate core die 20c may be directly bonded to a backside insulating layer 26b on the backside surface of the second-stage intermediate core die 20b. When the second-stage intermediate core die 20b and the third-stage intermediate core die 20c are bonded to each other by die-to-die bonding, a second bonding pad 27b of the second-stage intermediate core die 20b and a first bonding pad 23c of the third-stage intermediate core die 20c may be bonded to each other by copper-copper hybrid bonding.

As illustrated in FIG. 18, the first gap filling portion 30-1 may be formed to fill gaps between the intermediate core dies 20a, 20b and 20c stacked in three stages (e.g., three layers) on the first wafer W1.

A filling layer may be formed to cover the intermediate core dies 20a, 20b and 20c stacked in three stages on the first wafer W1, and an upper portion of the filling layer may be removed to form the first gap filling portion 30-1 that exposes upper surfaces of the third-stage intermediate core dies 20c. For example, the first gap filling portion 30-1 may be formed by a conformal deposition process such as an atomic layer deposition (ALD) process or a chemical vapor deposition (CVD) process. The first gap filling portion may include or be formed of an inorganic dielectric layer or an organic dielectric layer. The inorganic dielectric layer may include or be formed of silicon oxide, silicon oxynitride, phosphosilicate glass (PSG), boro-phosphosilicate glass (BPSG), etc. The organic dielectric layer may include or be formed of a polymer or the like. The upper portion of the filling layer may be removed by a chemical mechanical polishing process or a mechanical grinding process.

Then, an upper surface of the first reconstructed wafer RW1, e.g., the upper surfaces of the third-stage intermediate core dies 20c, may be planarized, e.g., to initialize a topology due to the stacking of the intermediate core dies 20a, 20b and 20c. For example, a chemical mechanical polishing (CMP) process may be performed to remove/offset topology accumulation in bonding interfaces of the third-stage intermediate core dies 20c (topology reset process).

Accordingly, the first reconstructed wafer RW1 including the intermediate core dies 20a, 20b, and 20c stacked in three stages and the first gap filling portion 30-1 covering the outer surfaces of the intermediate core dies 20a, 20b, 20c may be formed.

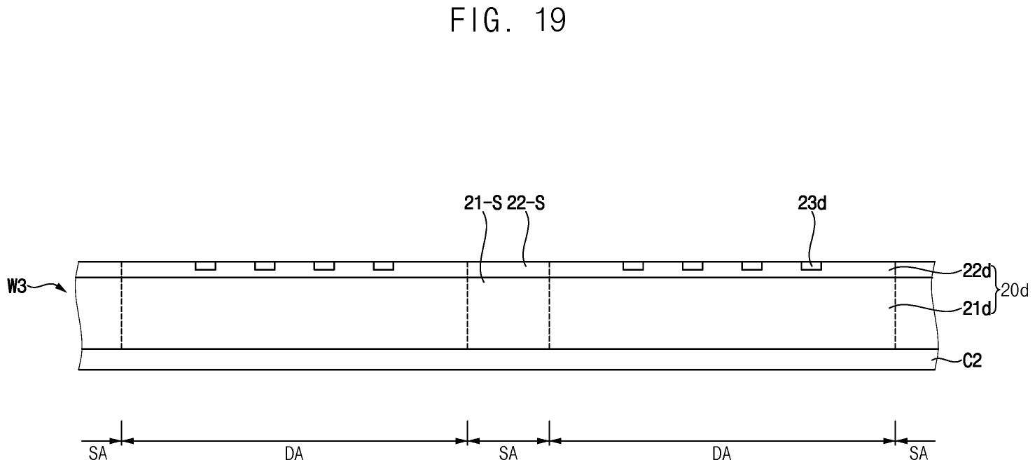

Referring to FIG. 19, a second reconstructed wafer RW2 including a top core die 20d and a second gap filling portion 21-S and 22-S covering an outer surface of the top core die 20d may be formed on a carrier substrate C2.

In example embodiments, a wafer W3 including the top core die 20d formed therein may be placed on the carrier substrate C2. The wafer W3 may be attached to the carrier substrate C2 using an adhesive film or an oxide layer. The wafer W3 may be stacked on the carrier substrate C2 such that a second surface (e.g., a backside surface or a non-active surface) 214d of a substrate 21d of the top core die 20d faces the carrier substrate C2. A thickness of the top core die 20d may be greater than thicknesses of the intermediate core dies 20a, 20b and 20c. The thickness of the top core die 20d may be in a range of 100 μm to 300 μm. The thicknesses of the intermediate core dies 20a, 20b, and 20c may be in a range of 20 μm to 50 μm.

The top core die 20d may include a first substrate region 21d corresponding to a die region DA (e.g., where circuit patterns and cells are formed) and a first front insulating layer region 22d provided on the first substrate region 21d, and the second gap filling portion may include a second substrate region 21-S corresponding to a scribe lane region SA and surrounding the first substrate region 21d and a second front insulating layer region 22-S provided on the second substrate region 21-S and surrounding the first front insulating layer region 22d. The first and second front insulating layer regions 22d and 22-S may include the front insulating layer 22 (e.g., 22b) of FIG. 6. The front insulating layer 22 may include a first insulating layer 222 and a first passivation layer 224. The first passivation layer 224 may include or be formed of silicon oxide, silicon nitride, or silicon carbonitride.

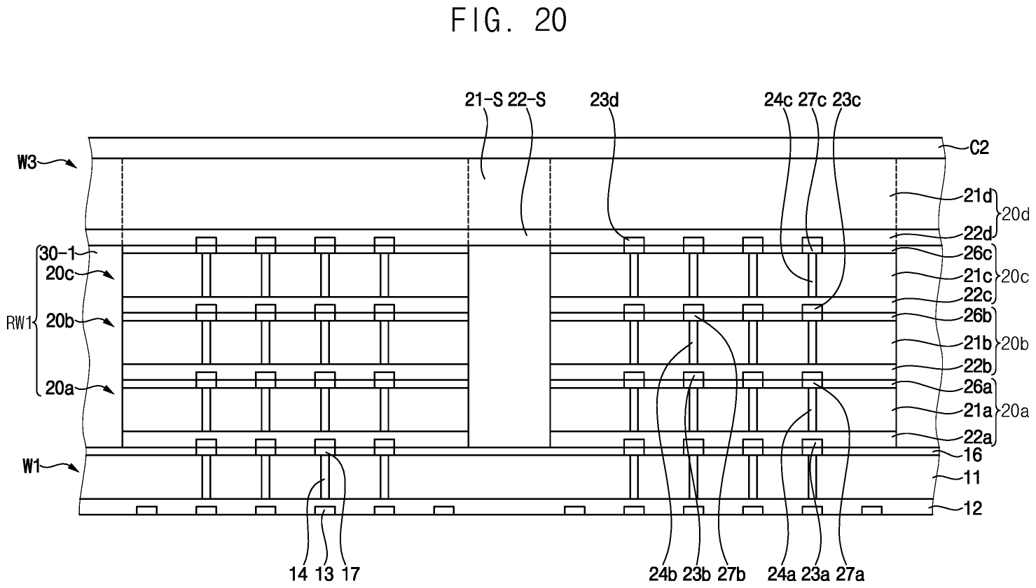

Referring to FIG. 20, the second reconstructed wafer RW2 may be attached to the first reconstructed wafer RW1 on the first wafer W1 (wafer-to-wafer hybrid bonding process).

In example embodiments, the second reconstructed wafer RW2 of FIG. 19 may be bonded to the first reconstructed wafer RW1 on the first wafer W1. The second reconstructed wafer RW2 may be stacked on the first reconstructed wafer RW1 such that a front surface of the top core die 20d of the second reconstructed wafer RW2 faces a backside surface of the intermediate core die 20c of the first reconstructed wafer RW1.

When the second reconstructed wafer RW2 and the first reconstructed wafer RW1 are bonded to each other by wafer-to-wafer bonding, the top core die 20d of the second reconstructed wafer RW2 and the intermediate core die 20c of the first reconstructed wafer RW1 may be hybrid-bonded to each other by a thermal compression process and an annealing process. For example, the first front insulating layer 22d on the front surface of the top core die 20d may be directly bonded to a backside insulating layer 26c on the backside surface of the intermediate core die 20c, and a second bonding pad 27c of the intermediate core die 20c and a first bonding pad 23d of the top core die 20d may be bonded to each other by copper-copper hybrid bonding (Cu—Cu Hybrid Bonding).

When the second reconstructed wafer RW2 and the first reconstructed wafer RW1 are bonded to each other by wafer-to-wafer bonding, the second gap filling portion of the second reconstructed wafer RW2 and the first gap filling portion 30-1 of the first reconstructed wafer RW1 may be bonded to each other by a thermal compression process and an annealing process. By the annealing process, the first gap filling portion 30-1 and the second front insulating layer region 22-S of the second gap filling portion may be directly bonded to each other to form a bonding interface layer. The bonding interface layer may have a thickness in a range of 2 Å to 500 Å. The bonding interface layer may include or be formed of silicon oxide.

In the existing die-to-wafer bonding process of the top core die, since the top core die has a relatively large thickness, it may be difficult to deform the top core die during the bonding, so voids generated at the bonding interface may not be discharged.

In example embodiments, the second reconstructed wafer RW2 including the top core die 20d and the first reconstructed wafer RW1 may be bonded to each other by wafer-to-wafer bonding. The second gap filling portion including the second substrate region 21-S and the second front insulating layer region 22-S may function as a flexibility compensating portion. For example, during the wafer-to-wafer bonding, the second reconstructed wafer RW2 may be brought into contact with the first reconstructed wafer RW1 while the center portion of the second reconstructed wafer RW2 is deformed to be convex downward. The central portion of the second reconstructed wafer RW2 and the central portion of the first reconstructed wafer RW1 may make contact with each other, and then, may be joined gradually from the central portion to the peripheral portion and the bonding proceeds in the radial direction. Accordingly, voids may be prevented from occurring at the bonding interface of the top core die 20d to thereby improve bonding quality.

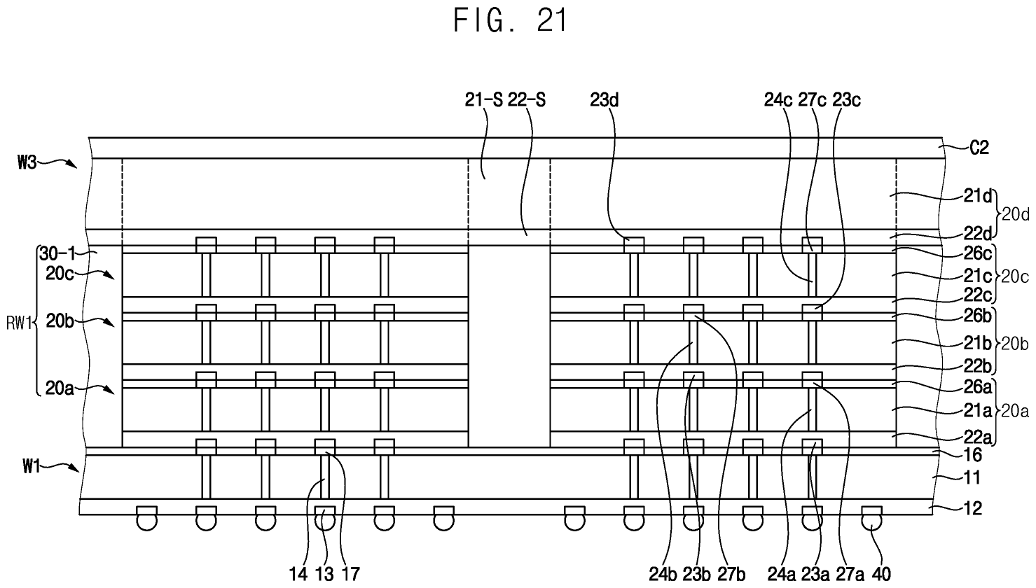

Referring to FIG. 21, conductive bumps 40 as conductive connection members may be formed on first bonding pads 13 of the first wafer W1.

For example, a seed layer may be formed on the first bonding pad 13 of the front insulating layer 12 of the first wafer W1, and a photoresist pattern having openings that expose portions of the seed layer may be formed on the seed layer on the front insulating layer 12. Then, the openings of the photoresist pattern may be filled up with a conductive material, the photoresist pattern may be removed and a reflow process may be performed to form solder bumps. For example, the conductive material may be formed on the seed layer by a plating process. Alternatively, each conductive bump 40 may include or be formed of a pillar bump and a solder bump formed on the pillar bump.

Then, the first wafer W1 and portions of the first and second gap filling portions 30-1, 21-S and 22-S may be cut along the scribe lane region SA to complete a semiconductor package 100 of FIG. 1.

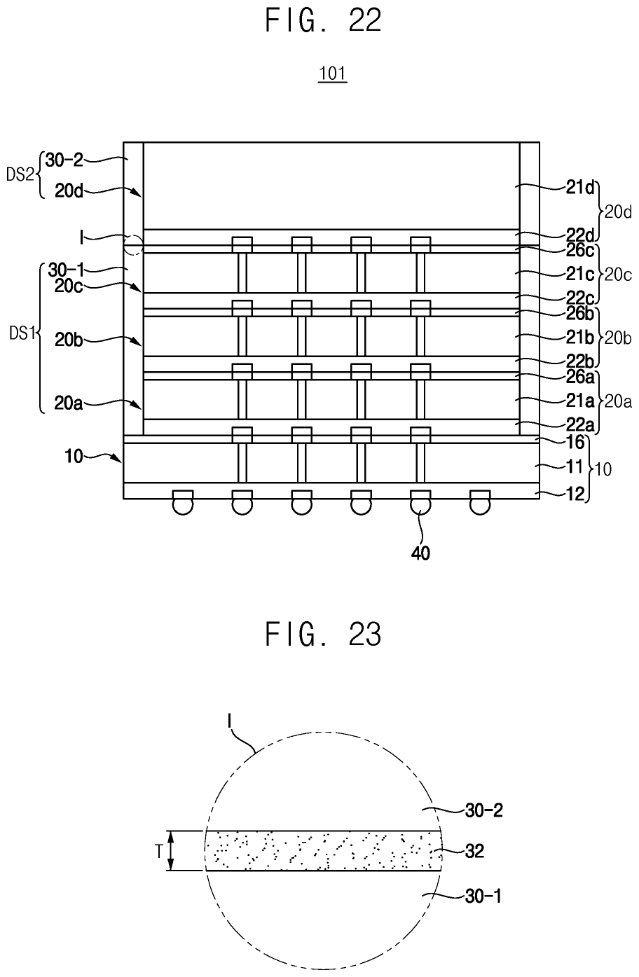

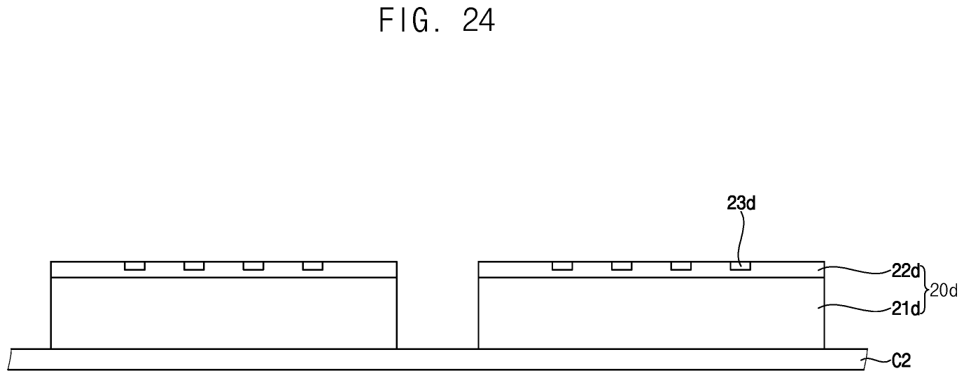

FIG. 22 is a cross-sectional view illustrating a semiconductor package according to example embodiments. FIG. 23 is an enlarged cross-sectional view illustrating portion ‘I’ in FIG. 22. The semiconductor package is the same as, substantially the same as or similar to the semiconductor package described with reference to FIG. 1 except for the number of stacked core dies and a configuration of a gap filling portion. Thus, same reference numerals will be used to refer to the same or like elements and any further repetitive explanation concerning the above elements will be omitted. For example, features of the embodiments of FIG. 23 that are not explained here may be the same as the features described above with respect to the semiconductor package 100 of FIG. 1.

Referring to FIGS. 22 and 23, a semiconductor package 101 may include semiconductor chips (dies) 20 (e.g., 20a, 20b, 20c and 20d) stacked therein. The semiconductor package 101 may include a buffer die 10, and an intermediate core die stack DS1 and a top core die stack DS2 sequentially stacked on the buffer die 10.

In example embodiments, the intermediate core die stack DS1 may be bonded onto the buffer die 10. The intermediate core die stack DS1 may include intermediate core dies 20a, 20b, and 20c stacked in three stages (e.g., three layers) and a first gap filling portion 30-1 covering outer surfaces of the intermediate core dies 20a, 20b, 20c.

The top core die stack DS2 may be bonded to the intermediate core die stack DS1. The top core die stack DS2 may include a top core die 20d stacked in one stage (e.g., one layer) and a second gap filling portion 30-2 covering an outer surface of the top core die 20d.

As illustrated in FIG. 23, when the top core die stack DS2 and the intermediate core die stack DS1 are bonded to each other, the second gap filling portion 30-2 of the top core die stack DS2 and the first gap filling portion 30-1 of the intermediate core die stack DS1 may be bonded to each other by a thermal compression process and an annealing process. By the annealing process, the first gap filling portion 30-1 and the second gap filling portion 30-2 may be directly bonded to each other to form a bonding interface layer. The bonding interface layer may include or be formed of silicon oxide.

Hereinafter, a method of manufacturing the semiconductor package of FIG. 22 will be described.

FIGS. 24 to 26 are views illustrating a method of manufacturing a semiconductor package according to example embodiments.

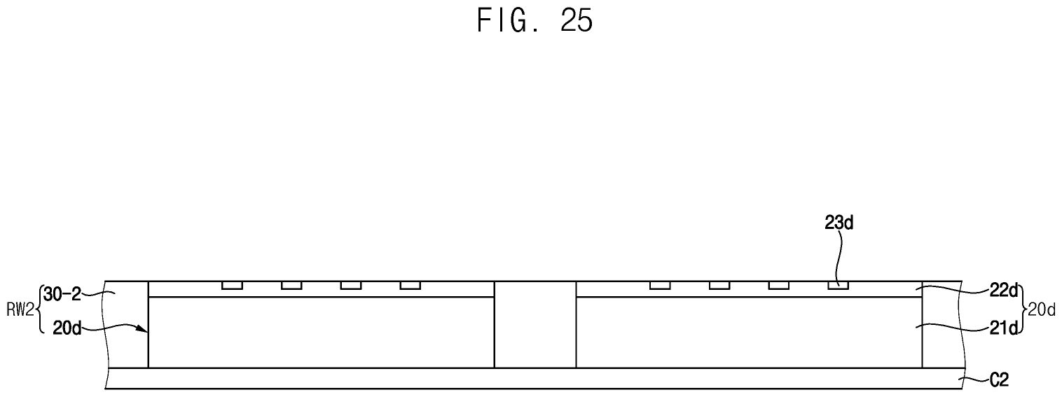

Referring to FIGS. 24 and 25, a second reconstructed wafer RW2 including a top core die 20d and a second gap filling 30-2 covering an outer surface of the top core die 20d may be formed on a carrier substrate C2.

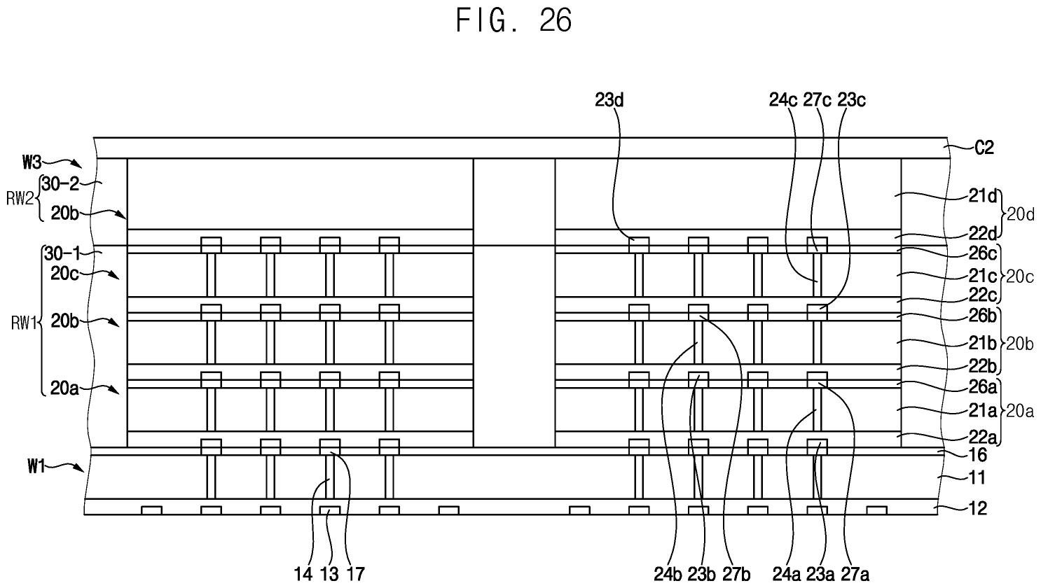

As illustrated in FIG. 24, a plurality of top core dies 20d may be attached in one stage on the carrier substrate C2. The top core dies 20d may be disposed on the carrier substrate C2 to correspond to die regions DA. For example, portions of the carrier substrate C2 on which the top core dies 20d are attached may form die regions DA of the carrier substrate C2. For example, the top core dies 20d may be disposed on the carrier substrate C2 in places which vertically overlap (e.g., fully overlap in a vertical direction) die regions DA of a first wafer W1 when the top core dies 20d and the carrier substrate C2 are attached on the first wafer W1 with a first reconstructed wafer RW1 interposed therebetween as shown in FIG. 26. The top core dies 20d may be attached to the carrier substrate C2 using an adhesive film or an oxide layer. The top core die 20d may be stacked on the carrier substrate C2 such that a second surface (e.g., a backside surface or a non-active surface) 214d of a substrate 21d of the top core die 20d faces the carrier substrate C2.

As illustrated in FIG. 25, the second gap filling portion 30-2 may be formed to fill gaps between the top core dies 20d stacked in one stage on the carrier substrate C2. A filling layer may be formed to cover the top core dies 20d stacked in one stage on the carrier substrate C2, and an upper portion of the filling layer may be removed to form the second gap filling portion 30-2 that exposes upper surfaces of the top core dies 20d. For example, the second gap filling portion 30-2 may be formed by a conformal deposition process such as an atomic layer deposition (ALD) process or a chemical vapor deposition (CVD) process. The second gap filling portion may include or be formed of an inorganic dielectric layer or an organic dielectric layer. The inorganic dielectric layer may include or be formed of silicon oxide, silicon oxynitride, phosphosilicate glass (PSG), and/or boro-phosphosilicate glass (BPSG). The organic dielectric layer may include or be formed of a polymer or the like. The upper portion of the filling layer may be removed by a chemical mechanical polishing process or a mechanical polishing process.

Accordingly, the second reconstructed wafer RW2 including the top core dies 20d stacked in one stage (e.g., formed of one layer) and the second gap filling portion 30-2 covering the outer surfaces of the top core dies 20d may be formed.

Referring to FIG. 26, the second reconstructed wafer RW2 may be attached to the first reconstructed wafer RW1 of FIG. 18 (wafer-to-wafer hybrid bonding process).

In example embodiments, the second reconstructed wafer RW2 of FIG. 25 may be bonded to the first reconstructed wafer RW1 on the first wafer W1. The second reconstructed wafer RW2 may be stacked on the first reconstructed wafer RW1 such that a front surface of the top core die 20d of the second reconstructed wafer RW2 faces a backside surface of the intermediate core die 20c of the first reconstructed wafer RW1.

When the second reconstructed wafer RW2 and the first reconstructed wafer RW1 are bonded to each other by wafer-to-wafer bonding, the top core die 20d of the second reconstructed wafer RW2 and the intermediate core die 20c of the first reconstructed wafer RW1 may be bonded to each other by hybrid bonding by a thermal compression process and an annealing process. For example, a front insulating layer 22d on the front surface of the top core die 20d may be directly bonded to the backside insulating layer 26c on the backside surface of the intermediate core die 20c, and a second bonding pad 27c of the intermediate core die 20c and a first bonding pad 23d of the top core die 20d may be bonded to each other by copper-copper hybrid bonding (Cu—Cu Hybrid Bonding).

When the second reconstructed wafer RW2 and the first reconstructed wafer RW1 are bonded to each other by wafer-to-wafer bonding, the second gap filing portion 30-2 of the second reconstructed wafer RW2 and the first gap filling portion 30-1 of the first reconstructed wafer RW1 may be bonded to each other by the thermal compression process and the annealing process. By the annealing process, the first gap filling portion 30-1 and the second gap filling portion 30-2 may be directly bonded to each other to form a bonding interface layer. The bonding interface layer may have a thickness in a range of 2 Å to 500 Å. The bonding interface layer may include or be formed of silicon oxide.

Then, processes the same as or similar to the processes described with reference to FIG. 21 may be performed to form conductive bumps 40 as conductive connection members on first bonding pads 13 of the first wafer W1.

Then, the first wafer W1 and portions of the first and second gap filling portions 30-1 and 30-2 may be cut along the scribe lane region SA to form a semiconductor package 101 of FIG. 22.

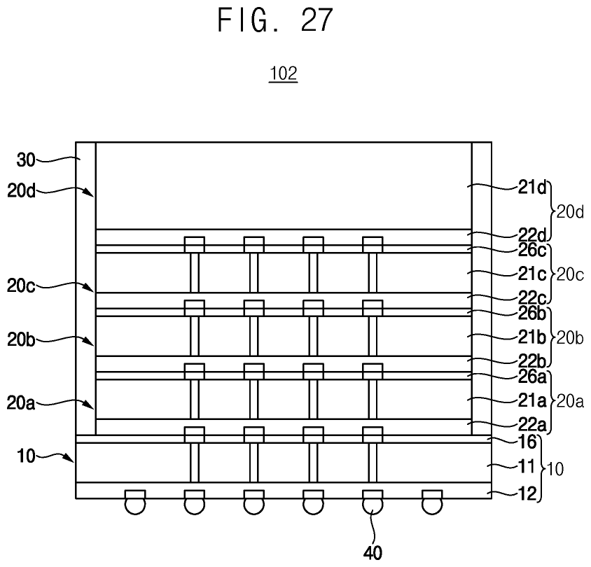

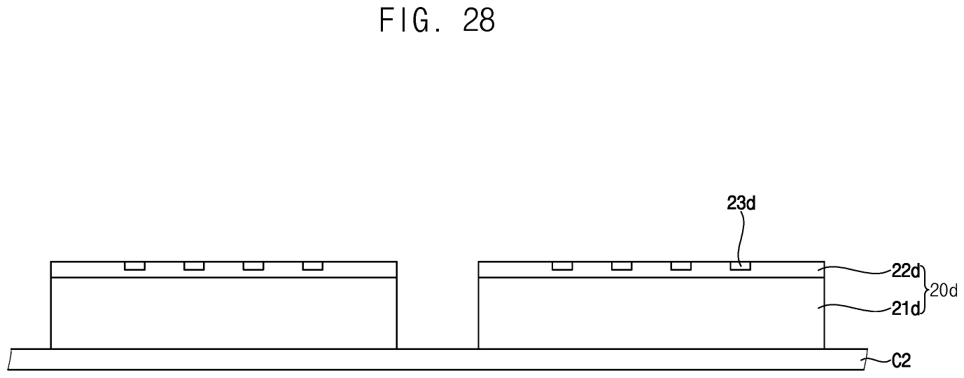

FIG. 27 is a cross-sectional view illustrating a semiconductor package according to example embodiments. The semiconductor package is the same as, substantially the same as or similar to the semiconductor package described with reference to FIG. 1 except for a configuration of a gap filling portion. Thus, same reference numerals will be used to refer to the same or like elements and any further repetitive explanation concerning the above elements will be omitted. For example, features of the embodiments of FIG. 27 that are not explained here may be the same as the features described above with respect to the semiconductor package 100 of FIG. 1.

Terms such as “same,” “equal,” “planar,” or “coplanar,” as used herein encompass identicality or near identicality including variations that may occur, for example, due to manufacturing processes. The term “substantially” may be used herein to emphasize this meaning, unless the context or other statements indicate otherwise.

Referring to FIG. 27, a semiconductor package 102 may include semiconductor chips (dies) 20 (e.g., 20a, 20b, 20c and 20d) stacked therein. The semiconductor package 102 may include a buffer die 10, intermediate core dies 20a, 20b and 20c and a top core die 20d sequentially stacked on the buffer die 10, and a gap filling portion 30 provided on the buffer die 10 and covering outer surfaces of the intermediate core dies 20a, 20b and 20c and the top core die 20d.

In example embodiments, the intermediate core dies 20a, 20b and 20c are sequentially bonded on the buffer die 10, and the top core die 20d may be bonded on the uppermost intermediate core die 20c. The gap filling portion 30 may cover the outer surfaces of the intermediate core dies 20a, 20b and 20c and the top core die 20d on the buffer die 10.

The gap filling portion 30 may expose an upper surface of the top core die 20d. For example, the gap filling portion 30 may be formed by a conformal deposition process such as an atomic layer deposition (ALD) process or a chemical vapor deposition (CVD) process. The gap filling portion may include or be formed of an inorganic dielectric layer or an organic dielectric layer. The inorganic dielectric layer may include or be formed of silicon oxide, silicon oxynitride, phosphosilicate glass (PSG), and/or boro-phosphosilicate glass (BPSG). The organic dielectric layer may include or be formed of a polymer or the like.

Hereinafter, a method of manufacturing the semiconductor package of FIG. 27 will be described.

FIGS. 28 to 31 are views illustrating a method of manufacturing a semiconductor package according to example embodiments.

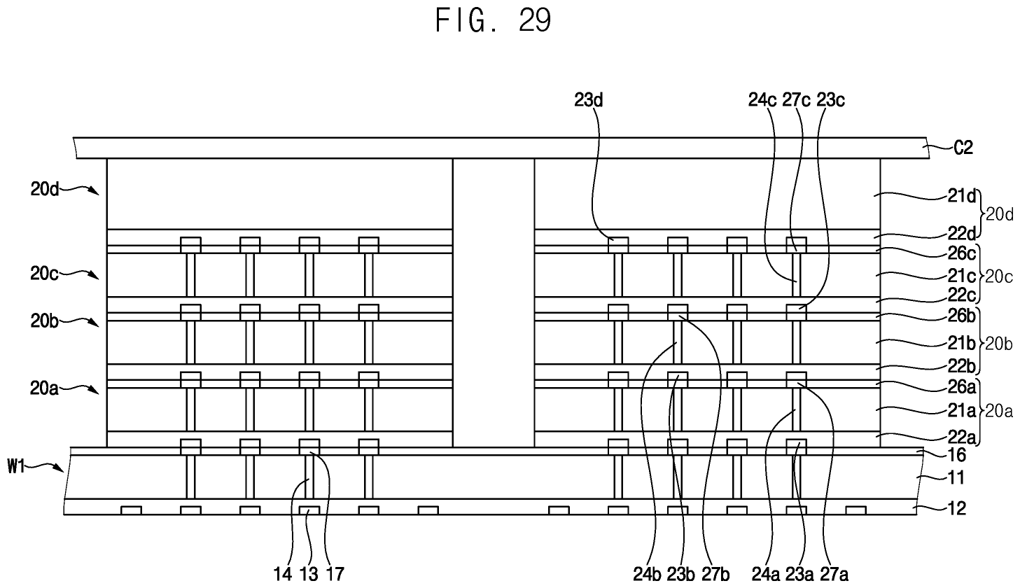

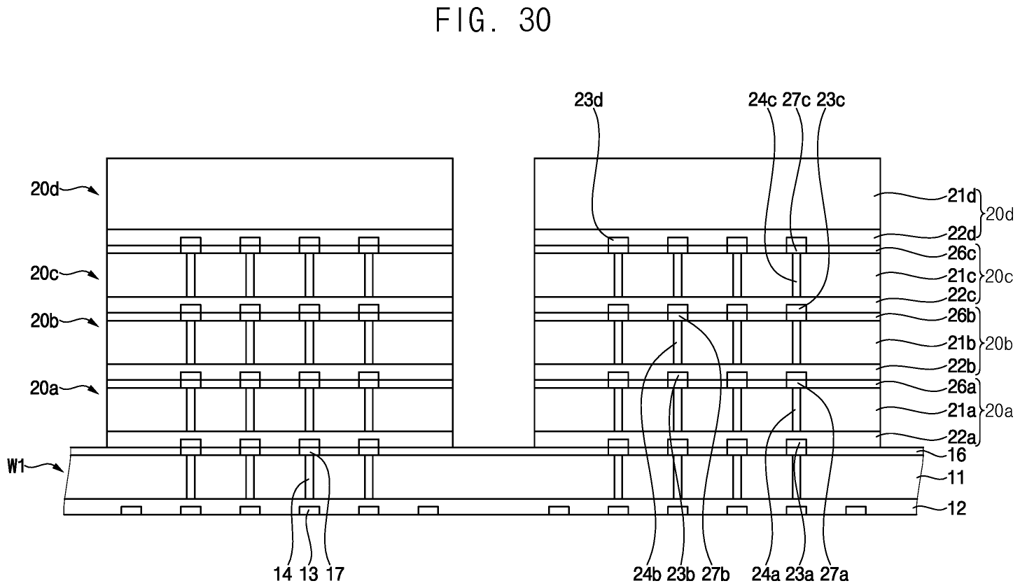

Referring to FIG. 28, a second reconstructed wafer including a plurality of top core dies 20d may be formed on a carrier substrate C2. The plurality of top core dies 20d may be attached in one stage on the carrier substrate C2. The top core dies 20d may be disposed on the carrier substrate C2 to correspond to die regions DA. For example, portions of the carrier substrate C2 on which the top core dies 20d are attached may form die regions DA of the carrier substrate C2. For example, the top core dies 20d may be disposed on the carrier substrate C2 in places which vertically overlap (e.g., fully overlap in a vertical direction) die regions DA of a first wafer W1 when the top core dies 20d and the carrier substrate C2 are attached on the first wafer W1 with a first reconstructed wafer RW1 interposed therebetween as shown in FIG. 29. The top core dies 20d may be attached to the carrier substrate C2 using an adhesive film or an oxide layer. The top core die 20d may be stacked on the carrier substrate C2 such that a second surface (e.g., a backside surface or a non-active surface) 214d of a substrate 21d of the top core die 20d faces the carrier substrate C2.

Referring to FIG. 29, the second reconstructed wafer may be attached to the first reconstructed wafer RW1 of FIG. 18 (wafer-to-wafer hybrid bonding process).

In exemplary embodiments, the second reconstructed wafer of FIG. 28 may be bonded to the first reconstructed wafer RW1 on the first wafer W1. The second reconstructed wafer may be stacked on the first reconstructed wafer RW1 such that a front surface of the top core die 20d of the second reconstructed wafer faces a backside surface of the intermediate core die 20c of the first reconstructed wafer RW1.

When the second reconstructed wafer and the first reconstructed wafer RW1 are bonded to each other by wafer-to-wafer bonding, the top core die 20d of the second reconstructed wafer and the intermediate core die 20c of the first reconstructed wafer RW1 may be bonded to each other by hybrid bonding by a thermal compression process and an annealing process. For example, a front insulating layer 22d on the front surface of the top core die 20d may be directly bonded to the backside insulating layer 26c on the backside surface of the intermediate core die 20c, and a second bonding pad 27c of the intermediate core die 20c and a first bonding pad 23d of the top core die 20d may be bonded to each other by copper-copper hybrid bonding (Cu—Cu Hybrid Bonding).

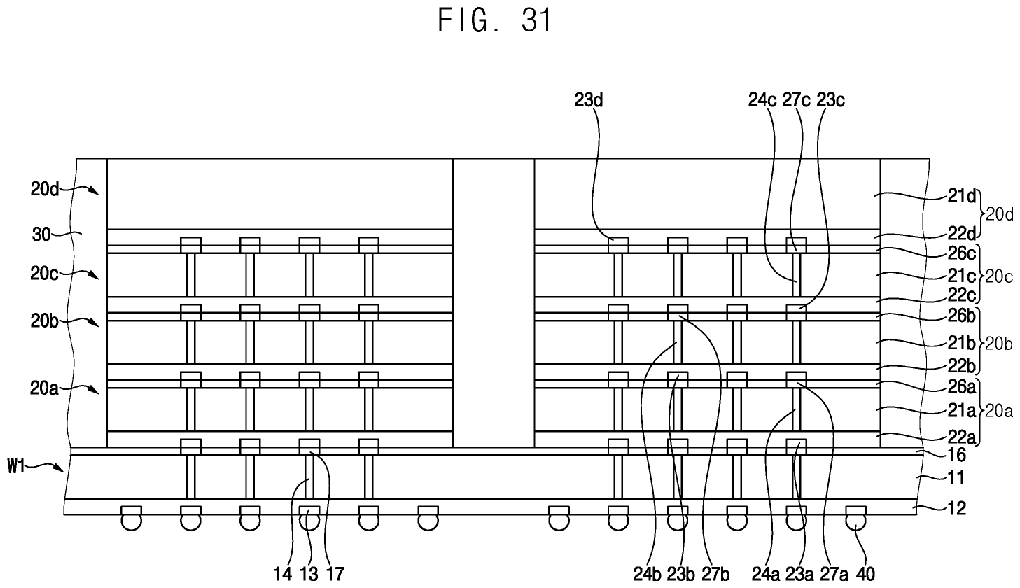

Referring to FIGS. 30 and 31, after the top core dies 20d are bonded to the uppermost intermediate core dies 20c, the carrier substrate C2 may be removed and a gap filling portion 30 may be formed to fill gaps between the intermediate core dies 20a, 20b and 20c and the top core dies 20d sequentially stacked on the first wafer W1. A filling layer may be formed to cover the core dies 20a, 20b, 20c, and 20d stacked in four stages (e.g., four layers) on the first wafer W1, and an upper portion of the filling layer may be removed to form the gap filling portion 30 that exposes upper surfaces of the top core dies 20d. For example, the gap filling portion 30 may be formed by a conformal deposition process such as an atomic layer deposition (ALD) process or a chemical vapor deposition (CVD) process. The gap filling portion may include or be formed of an inorganic dielectric layer or an organic dielectric layer. The inorganic dielectric layer may include or be formed of silicon oxide, silicon oxynitride, phosphosilicate glass (PSG), and/or boro-phosphosilicate glass (BPSG). The organic dielectric layer may include or be formed of a polymer or the like. The upper portion of the filling layer may be removed by a chemical mechanical polishing process or a mechanical polishing process.

Then, processes the same as or similar to the processes described with reference to FIG. 21 may be performed to form conductive bumps 40 as conductive connection members on first bonding pads 13 of the first wafer W1.

Then, the first wafer W1 and a portion of the gap filling portion 30 may be cut along the scribe lane region SA to form a semiconductor package 102 of FIG. 27.

The semiconductor package may include or may be a semiconductor device such as a logic device or a memory device. The semiconductor package may include or may be logic device such as a central processing unit (CPU), a main processing unit (MPU), or an application processor (AP), or the like, and a volatile memory device such as a DRAM device, an HBM device, or a non-volatile memory device such as a flash memory device, a PRAM device, an MRAM device, a ReRAM device, or the like.

Even though different figures illustrate variations of exemplary embodiments and different embodiments disclose different features from each other, these figures and embodiments are not necessarily intended to be mutually exclusive from each other. Rather, features depicted in different figures and/or described above in different embodiments can be combined with other features from other figures/embodiments to result in additional variations of embodiments, when taking the figures and related descriptions of embodiments as a whole into consideration. For example, components and/or features of different embodiments described above can be combined with components and/or features of other embodiments interchangeably or additionally to form additional embodiments unless the context clearly indicates otherwise, and the present disclosure includes the additional embodiments.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of the claims.

What is claimed is:

1. A semiconductor package, comprising:
a buffer die;
an intermediate core die stack stacked on the buffer die, the intermediate core die stack including a plurality of intermediate core dies and a first gap filling portion covering outer surfaces of the plurality of intermediate core dies; and
a top core die stack stacked on the intermediate core die stack, the top core die stack including a top core die and a second gap filling portion covering an outer surface of the top core die,
wherein the first gap filling portion and the second gap filling portion are directly bonded to each other.

2. The semiconductor package of claim 1, wherein each of the intermediate core dies includes,
a substrate;
a front insulating layer provided on a front surface of the substrate;
a first bonding pad formed in the front insulating layer; and
a backside insulating layer provided on a backside surface of the substrate; and
a second bonding pad formed in the backside insulating layer.

3. The semiconductor package of claim 2, wherein the backside insulating layer of a first intermediate core die among the plurality of intermediate core dies and the front insulating layer of a second intermediate core die stacked on the first intermediate core die are directly bonded to each other, and
wherein the second bonding pad of the first intermediate core die and the first bonding pad of the second intermediate core die are directly bonded to each other.

4. The semiconductor package of claim 2, wherein the front insulating layer and the backside insulating layer include silicon oxide, silicon nitride, or silicon carbonitride.

5. The semiconductor package of claim 2, wherein each of the intermediate core dies further includes a through electrode that penetrates the substrate and is electrically connected to the first and second bonding pads.

6. The semiconductor package of claim 1, wherein the first gap filling portion includes an inorganic dielectric or an organic dielectric.

7. The semiconductor package of claim 1, wherein the top core die includes a first substrate region and a first front insulating layer region provided on the first substrate region, and the second gap filling portion includes a second substrate region surrounding the first substrate region and a second front insulating layer region provided on the second substrate region and surrounding the first front insulating layer region.

8. The semiconductor package of claim 7, wherein the second front insulating layer region is directly bonded to the first gap filling portion to form a bonding interface layer.

9. The semiconductor package of claim 8, wherein the bonding interface layer has a thickness in a range of 2 Å to 500 Å.

10. The semiconductor package of claim 1, wherein the second gap filling portion includes an inorganic dielectric or an organic dielectric.

11. A semiconductor package, comprising:
a buffer die;
an intermediate core die stack stacked on the buffer die, the intermediate core die stack including a plurality of intermediate core dies and a gap filling portion covering outer surfaces of the plurality of intermediate core dies; and
a top core die stack stacked on the intermediate core die stack, the top core die stack including a top core die and a flexibility compensating portion covering an outer surface of the top core die,
wherein each of the plurality of intermediate core dies includes a substrate, a front insulating layer provided on a front surface of the substrate, a first bonding pad provided in the front insulating layer, a backside insulating layer provided on a backside surface of the substrate, and a second bonding pad provided in the backside insulating layer, and
wherein the gap filling portion and the flexibility compensating portion are directly bonded to each other.

12. The semiconductor package of claim 11, wherein the backside surface of the substrate of a first intermediate core die among the plurality of intermediate core dies and the front surface of the substrate of a second intermediate core die are arranged to face each other.

13. The semiconductor package of claim 12, wherein the backside insulating layer of the first intermediate core die and the front insulating layer of the second intermediate core die are directly bonded to each other, and
wherein the second bonding pad of the first intermediate core die and the first bonding pad of the second intermediate core die are directly bonded to each other.

14. The semiconductor package of claim 11, wherein the front insulating layer and the backside insulating layer include silicon oxide, silicon nitride, or silicon carbonitride.

15. The semiconductor package of claim 11, wherein the first and second bonding pads include copper.

16. The semiconductor package of claim 11, wherein the top core die includes a first substrate region and a first front insulating layer region provided on the first substrate region, and the flexibility compensating portion includes a second substrate region surrounding the first substrate region and a second front insulating layer region provided on the second substrate region and surrounding the first front insulating layer region.

17. The semiconductor package of claim 16, wherein the second front insulating film region is directly bonded to the gap filling portion to form a bonding interface layer.

18. The semiconductor package of claim 17, wherein the bonding interface layer has a thickness in a range of 2 Å to 500 Å.

19. The semiconductor package of claim 11, wherein a thickness of the top core die is in a range of 100 μm to 300 μm, and a thickness of each of the intermediate core dies is in a range of 20 μm to 50 μm.

20. A semiconductor package, comprising:
a buffer die;
an intermediate core die stack stacked on the buffer die; and
a top core die stack stacked on the intermediate core die stack,
wherein the intermediate core die stack includes a plurality of intermediate core dies stacked on one another and a gap filling portion covering outer surfaces of the intermediate core dies,
wherein the top core die stack includes a top core die and a flexibility compensating portion covering an outer surface of the top core die,
wherein each of the plurality of intermediate core dies includes,
a substrate;
a front insulating layer provided on a front surface of the substrate;
a first bonding pad provided in the front insulating layer;
a backside insulating layer provided on a backside surface of the substrate; and
a second bonding pad provided in the backside insulating layer.
